(19) United States
(12) Patent Application Publication
(10) Pub. No.: US 2013/0161722 A1
(43) Pub. Date: Jun. 27, 2013

(54) SEMICONDUCTOR DEVICES AND METHODS OF MANUFACTURING THE SAME

(71) Applicant: SAMSUNG ELECTRONICS CO., LTD., Suwon-Si (KR)

(72) Inventors: Sung-Ho SON, Hwaseong-si (KR); Yoon-Hae KIM, Yongin-si (KR); Hong-Seong KANG, Seoul (KR); Yoon-Seok LEE, Seoul (KR); Junjie XIONG, Suwon-si (KR)

(73) Assignee: SAMSUNG ELECTRONICS CO., LTD., Suwon-Si (KR)

(21) Appl. No.: 13/712,109

(22) Filed: Dec. 12, 2012

(30) Foreign Application Priority Data
Dec. 26, 2011 (KR) 10-2011-0142292

(51) Int. Cl. H01L 29/78; H01L 29/788

(52) U.S. Cl. CPC H01L 29/78; H01L 29/788
USPC 257/321; 257/379

(57) ABSTRACT

A semiconductor device may include a gate structure on a substrate, the gate structure including a first metal; an insulating interlayer covering the gate structure on the substrate; a resistance pattern in the insulating interlayer, the resistance pattern having a top surface lower than a top surface of the insulating interlayer and including a second metal different from the first metal at least at an upper portion thereof; and/or a first contact plug through a first portion of the insulating interlayer, the first contact plug making direct contact with the upper portion of the resistance pattern.

### CROSS-REFERENCE TO RELATED APPLICATION(S)

This application claims priority from Korean Patent Application No. 2011-0142292, filed on Dec. 26, 2011, in the Korean Intellectual Property Office (KIPO), the entire contents of which are incorporated herein by reference.

### BACKGROUND

1. Field

Example embodiments may relate to semiconductor devices and/or methods of manufacturing the same. Example embodiments may relate to semiconductor devices having a resistance pattern and/or methods of manufacturing the semiconductor devices.

2. Description of the Related Art

Doped polysilicon has been used for a resistance pattern in a semiconductor device. However, a method of forming a metal resistance pattern has been developed according as a high performance metal gate has been used. Thus, a method of forming a resistance pattern having good electrical characteristics is desired.

### SUMMARY

Example embodiments may provide semiconductor devices including resistance patterns having good characteristics.

Example embodiments may provide methods of manufacturing semiconductor devices including resistance patterns having good characteristics.

In some example embodiments, a semiconductor device may comprise a gate structure on a substrate, the gate structure including a first metal; an insulating interlayer covering the gate structure on the substrate; a resistance pattern in the insulating interlayer, the resistance pattern having a top surface lower than a top surface of the insulating interlayer and including a second metal different from the first metal at least at an upper portion thereof; and/or a first contact plug through a first portion of the insulating interlayer, the first contact plug making direct contact with the upper portion of the resistance pattern.

In some example embodiments, the substrate may be divided into an active region and a field region. The semiconductor device may further comprise at least one second contact plug through a second portion of the insulating interlayer, the at least one second contact plug being electrically connected to the active region; and/or a shared contact plug through the insulating interlayer, the shared contact plug making contact with a top surface of the gate structure and a top surface of the second contact plug.

In some example embodiments, the first contact plug and the shared contact plug may have top surfaces substantially coplanar with each other.

In some example embodiments, the insulating interlayer may include an etch stop layer having a bottom surface coplanar with a top surface of the second contact plug.

In some example embodiments, the semiconductor device may further comprise a third contact plug through a third portion of the insulating interlayer and the etch stop layer, the third contact plug making contact with a top surface of the second contact plug that does not contact the shared contact plug and having a top surface substantially coplanar with a top surface of the first contact plug.

In some example embodiments, the resistance pattern may include tungsten or tungsten silicide.

In some example embodiments, the semiconductor device may further comprise an alignment key in the insulating interlayer, the alignment key having a bottom surface coplanar with a bottom surface of the resistance pattern and including the second metal.

In some example embodiments, a bottom surface of the resistance pattern may be lower than a top surface of the gate structure.

In some example embodiments, a bottom surface of the resistance pattern may be higher than a top surface of the gate structure.

In some example embodiments, the gate structure may include a tunnel insulation layer pattern, a floating gate, a dielectric layer pattern, and a control gate sequentially stacked on the substrate. The control gate may include the first metal.

In some example embodiments, a semiconductor device may comprise a gate structure on a cell region of a substrate that is divided into an active region and a field region, and includes the cell region and a logic region, the gate structure including a first metal; an insulating interlayer covering the gate structure on the substrate; a resistance pattern in the insulating interlayer in the logic region, the resistance pattern having a top surface lower than a top surface of the insulating interlayer and including a second metal different from the first metal; a first contact plug through a portion of the insulating interlayer, the first contact plug making contact with a top surface of the resistance pattern; at least one second contact plug through the insulating interlayer in the cell region, the at least one second contact plug being electrically connected to the active region; and/or a shared contact plug through the insulating interlayer in the cell region, the shared contact plug making contact with a top surface of the gate structure and a top surface of the at least one second contact plug.

In some example embodiments, a semiconductor device may comprise a gate structure on a cell region of a substrate including the cell region and a logic region; an insulating interlayer covering the gate structure on the substrate; a resistance pattern in the insulating interlayer in the logic region, the resistance pattern having a top surface lower than a top surface of the insulating interlayer; a first contact plug through a portion of the insulating interlayer, the first contact plug making contact with a top surface of the resistance pattern; and/or a second contact plug through the insulating interlayer in the cell region, the second contact plug making contact with a top surface of the gate structure, including a material substantially the same as that of the first contact plug, and having a top surface substantially coplanar with a top surface of the first contact plug.

In some example embodiments, a method of manufacturing a semiconductor device may comprise forming a gate structure including a first metal on a substrate; forming an insulating interlayer on the substrate to cover the gate structure; partially removing an upper portion of the insulating interlayer to form a trench; forming a resistance pattern in the trench, the resistance pattern having a top surface lower than a top surface of the insulating interlayer and including a second metal different from the first metal; filling a remaining portion of the trench using a material substantially the same as that of the insulating interlayer; and/or forming a contact plug through a portion of the insulating interlayer, the contact plug making direct contact with a top surface of the resistance pattern.

In some example embodiments, partially removing an upper portion of the insulating interlayer to form a trench may include partially removing an upper portion of the insulating interlayer to form an alignment key recess.

In some example embodiments, forming a resistance pattern may comprise forming a resistance layer on the insulating interlayer having the trench and the alignment key recess thereon; sufficiently fill remaining portions of the trench and the alignment key recess using the material substantially the same as that of the insulating interlayer; forming a photoresist pattern on the insulating interlayer; and/or patterning the resistance layer using the photoresist pattern.

In some example embodiments, patterning the resistance layer using the photoresist pattern may include forming an alignment key in the alignment key recess.

In some example embodiments, a semiconductor device may comprise a substrate including a cell region, a logic region, and a scribe lane region; a gate structure on the substrate in the cell region; an insulating interlayer on the substrate in the cell region, the logic region, and the scribe lane region; a resistance pattern in the insulating interlayer on the substrate in the logic region; and/or a first contact plug through a portion of the insulating interlayer on the substrate in the logic region. The gate structure may include a first metal and/or the resistance pattern may include a second metal different from the first metal.

In some example embodiments, the resistance pattern may have a top surface lower than a top surface of the insulating interlayer.

In some example embodiments, the first contact plug may make direct contact with an upper portion of the resistance pattern.

In some example embodiments, the resistance pattern may include tungsten.

In some example embodiments, the resistance pattern may include tungsten silicide.

In some example embodiments, the gate structure may include a tunnel insulation layer pattern, a floating gate, a dielectric layer pattern, and a control gate sequentially stacked on the substrate.

In some example embodiments, a top surface of the resistance pattern may be lower than a top surface of the insulating interlayer.

In some example embodiments, the semiconductor device may further comprise an alignment key in the insulating interlayer on the substrate in the scribe lane region.

In some example embodiments, the alignment key may have a bottom surface that is coplanar with a bottom surface of the resistance pattern.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIG. 1 is a cross-sectional view illustrating a semiconductor device in accordance with example embodiments;

FIG. 2 is a cross-sectional view illustrating a semiconductor device in accordance with example embodiments;

FIGS. 3 to 19 are cross-sectional views illustrating stages of a method of manufacturing a semiconductor device in accordance with example embodiments;

FIGS. 20 to 22 are cross-sectional views illustrating stages of a method of manufacturing a semiconductor device in accordance with example embodiments;

FIG. 23 is a cross-sectional view illustrating a semiconductor device in accordance with example embodiments;

FIGS. 24 to 25 are cross-sectional views illustrating stages of a method of manufacturing a semiconductor device in accordance with example embodiments;

FIG. 26 is a cross-sectional view illustrating a semiconductor device in accordance with example embodiments; and

FIGS. 27 to 33 are cross-sectional views illustrating stages of a method of manufacturing a semiconductor device in accordance with example embodiments.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

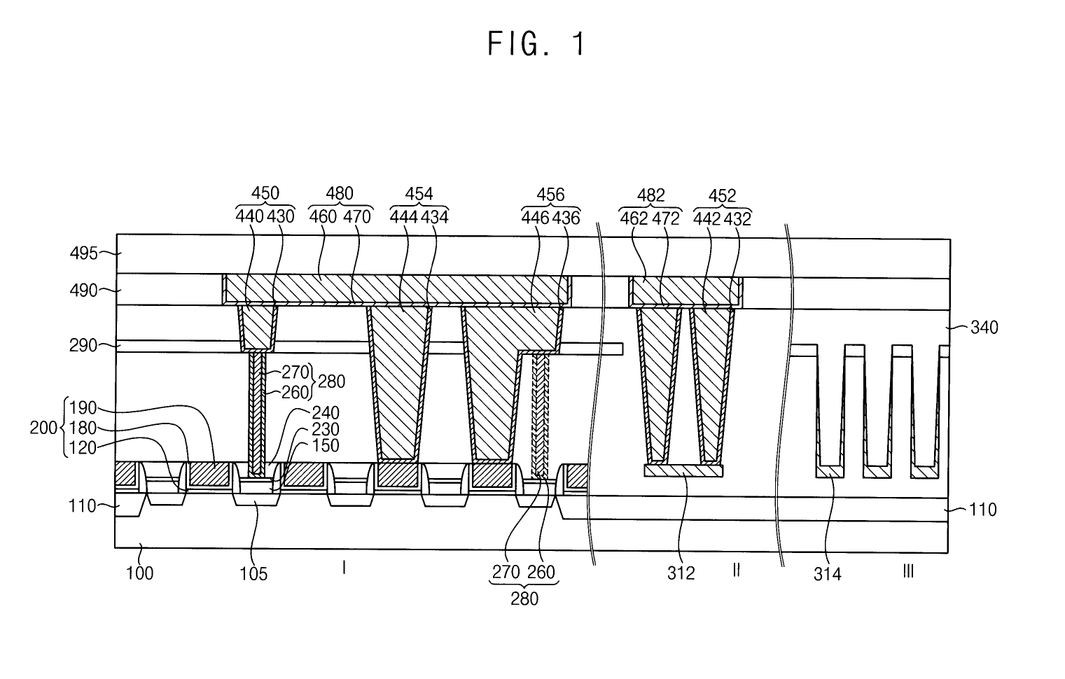

FIG. 1 is a cross-sectional view illustrating a semiconductor device in accordance with example embodiments.

Referring to FIG. 1, the semiconductor device may include a gate structure 200, a first insulating interlayer 340, a first resistance pattern 312 and a first contact plug 452. The semiconductor device may further include second, third and fourth contact plugs 280, 450 and 454, a shared contact plug 456 and a first alignment key 314.

The substrate 100 may be a silicon substrate, a germanium substrate, a silicon-germanium substrate, a silicon on insulator (SOI) substrate or a germanium on insulator (GOI) substrate. The substrate 100 may be divided into a field region in which an isolation layer 110 is formed and an active region in which the isolation layer 110 is not formed.

The substrate 100 may include a cell region I in which memory cells may be formed, a logic region II in which peripheral circuits for driving the memory cells and a resistance pattern may be formed, and a scribe lane region III in which alignment keys for aligning devices and/or chips may be formed. The logic region II may include a peripheral circuit region for the peripheral circuits and a resistance region for the resistance pattern, and only the resistance region is illustrated in FIG. 1 for the convenience of explanation.

The gate structure 200 may include a low-k dielectric layer pattern 120, a high-k dielectric layer pattern 180 and a gate electrode 190, and a gate spacer 140 may be formed on a sidewall of the gate structure 200. The low-k dielectric layer pattern 120 and the high-k dielectric layer pattern 180 may serve as a gate insulation layer pattern, and in an example embodiment, the low-k dielectric layer pattern 120 may not be formed. In example embodiments, the high-k dielectric layer pattern 180 may be formed on the low-k dielectric layer pattern 120 and surround a bottom and a side wall of the gate electrode 190.

The low-k dielectric layer pattern 120 may include, e.g., silicon oxide, and the high-k dielectric layer pattern 180 may include a metal oxide, e.g., hafnium oxide, tantalum oxide, zirconium oxide, etc. The gate electrode 190 may include a low resistance metal, e.g., aluminum, copper, etc., and the gate spacer 140 may include, e.g., silicon nitride.

In example embodiments, a plurality of gate structures 200 may be formed in the cell region I of the substrate 100, and accordingly a plurality of gate spacers 140 that may be formed on sidewalls of the gate structures 200 may be formed.

An impurity region 105 and an elevated source drain (ESD) layer 150 may be further formed adjacent to the gate structure 200, and the gate structure 200, the impurity region 105 and the ESD layer 150 may form a transistor.

The impurity region 105 may be formed at an upper portion of the active region of the substrate 100 adjacent to the gate structure 200. In example embodiments, the impurity region 105 may include single crystalline silicon-germanium doped with p-type impurities, e.g., boron, or single crystalline silicon carbide doped with n-type impurities, e.g., phosphorus.

In example embodiments, the ESD layer 150 may be formed on the impurity region 105 and make contact with the gate spacer 140. The ESD layer 150 may include single crystalline silicon doped with impurities having a conduction type substantially the same as that of the impurity region 105 therebeneath. For example, the ESD layer 150 may include single crystalline silicon doped with p-type impurities, e.g., boron, or single crystalline silicon doped with n-type impurities, e.g., phosphorus. In an example embodiment, the ESD layer 150 may not be formed.

When the impurity region 105 and the ESD layer 150 include p-type impurities, the impurity region 105 and the ESD layer 150 together with an adjacent gate structure 200 may form a p-channel metal oxide semiconductor (PMOS) transistor. When the impurity region 105 and the ESD layer 150 include n-type impurities, the impurity region 105 and the ESD layer 150 together with an adjacent gate structure 200 may form an n-channel metal oxide semiconductor (NMOS)transistor.

In example embodiments, the semiconductor device may be a static random access memory (SRAM) device, and the transistor may be a drive transistor, a load transistor or an access transistor of the SRAM device.

The first insulating interlayer 340 may be formed on the whole region of the substrate 100 to cover the gate structure 200 and the gate spacer 140.

In example embodiments, the first insulating interlayer 340 may include silicon oxide. The first insulating interlayer 340 may include an etch stop layer 290 therein. In example embodiments, the etch stop layer 290 may include silicon nitride.

The first resistance pattern 312 may be formed in the first insulating interlayer 340 in the resistance region of the logic region II, and may have a top surface lower than that of the first insulating interlayer 340. At least a portion of the top surface of the first resistance pattern 312 may be covered by the first insulating interlayer 340. In an example embodiment, a bottom surface of the first resistance pattern 312 may be lower than a top surface of the gate structure 200.

The first resistance pattern 312 may include a metal and/or a metal silicide, which may be different from a metal of the gate electrode 190, at least at an upper portion thereof. For example, the first resistance pattern 312 may include tungsten or tungsten silicide having a resistance greater than a metal of the gate electrode 190.

The first contact plug 452 may be formed through a portion of the first insulating interlayer 340 to make contact with the top surface of the first resistance pattern 312. Thus, the first contact plug 452 may make direct contact with the top surface of the first resistance pattern 312 including a metal or a metal silicide. In example embodiments, the first contact plug 452 may have a top surface coplanar with that of the first insulating interlayer 340.

In an example embodiment, the first contact plug 452 may include a first conductive layer pattern 442 and a first barrier layer pattern 432 surrounding a bottom and a sidewall of the first conductive layer pattern 442. The first conductive layer pattern 442 may include a metal, a metal nitride and/or a metal silicide, and the first barrier layer pattern 432 may include a metal or a metal nitride.

The second contact plug 280 may be formed through a portion of the first insulating interlayer 340 and an insulation layer 240 surrounding the gate spacers 140 to make contact with a top surface of the ESD layer 150. Thus, the second contact plug 280 may be electrically connected to the impurity region 105 adjacent to the gate structure 200. When the ESD layer 150 is not formed, the second contact plug 280 may make direct contact with a top surface of the impurity region 105. In an example embodiment, a metal silicide pattern 230 may be formed on the ESD layer 150, and in this case, the second contact plug 280 may make contact with the metal silicide pattern 230.

In example embodiments, the second contact plug 280 may have a top surface coplanar with a bottom surface of the etch stop layer 290. In example embodiments, a plurality of second contact plugs 280 may be formed in the cell region I.

The second contact plug 280 may include a second conductive layer pattern 270 and a second barrier layer pattern 260 surrounding a bottom and a sidewall of the second conductive layer pattern 270. The second conductive layer pattern 270 may include doped polysilicon, a metal, a metal nitride and/or a metal silicide. The second barrier layer pattern 260 may include a metal or a metal nitride.

The insulation layer 240 may include, e.g., silicon oxide, and the metal silicide pattern 230 may include, e.g., nickel silicide, cobalt silicide, platinum silicide, etc.

The third contact plug 450 may be formed through a portion of the first insulating interlayer 340 and the etch stop layer 290 to make contact with a top surface of the second contact plug 280. In example embodiments, the third contact plug 450 may have a top surface coplanar with the top surface of the first insulating interlayer 340, thereby having the top surface coplanar with the top surface of the first contact plug 452.

The third contact plug 450 may include a third conductive layer pattern 440 and a third barrier layer pattern 430 surrounding a bottom and a sidewall of the third conductive layer pattern 440. The third conductive layer pattern 440 may include doped polysilicon, a metal, a metal nitride and/or a metal silicide. The third barrier layer pattern 430 may include a metal or a metal nitride.

The fourth contact plug 454 may be formed through the first insulating interlayer 340 and the etch stop layer 290 to make contact with the top surface of the gate structure 200. In example embodiments, the fourth contact plug 454 may have a top surface coplanar with the top surface of the first insulating interlayer 340, thereby having the top surface coplanar with the top surfaces of the first and third contact plugs 452 and 450.

The fourth contact plug 454 may include a fourth conductive layer pattern 444 and a fourth barrier layer pattern 434 surrounding a bottom and sidewall of the fourth conductive layer pattern 444. The fourth conductive layer pattern 444 may include doped polysilicon, a metal, a metal nitride and/or a metal silicide. The fourth barrier layer pattern 434 may include a metal or a metal nitride.

The shared contact plug 456 may be formed through the first insulating interlayer 340 and the etch stop layer 290 to make contact with both of the top surface of the gate structure 200 and the top surface of the second contact plug 280. Thus, the gate structure 200 and the impurity region 105 may share the shared contact plug 456. However, the gate structure 200 and the impurity region 105 sharing the shared contact plug 456 may be included in transistors of different conduction types. That is, a gate structure 200 of a PMOS transistor and an impurity region 105 of an NMOS transistor may share the shared contact plug 456, or a gate structure 200 of an NMOS transistor and an impurity region 105 of a PMOS transistor may share the shared contact plug 456. Thus, the second contact plug 280 making contact with the shared contact plug 456 is illustrated as a dotted line in FIG. 1, which shows that the second contact plug 280 makes contact with an impurity region 105 included in a transistor having a conduction type different from that of a transistor including a gate structure 200 making contact with the shared contact plug 456.

In example embodiments, the shared contact plug 456 may have a top surface coplanar with the top surface of the first insulating interlayer 340, and thus coplanar with those of the first, third and fourth contact plugs 452, 450 and 454.

The shared contact plug 456 may include a fifth conductive layer pattern 446 and a fifth barrier layer pattern 436 surrounding a bottom and a sidewall of the fifth conductive layer pattern 446. The fifth conductive layer pattern 446 may include a metal, a metal nitride and/or a metal silicide, and the fifth barrier layer pattern 436 may include a metal or a metal nitride.

The first alignment key 314 may be formed in the first insulating interlayer 340 in the scribe lane region III. In example embodiments, the first alignment key 314 may have a bottom surface coplanar with a bottom surface of the first resistance pattern 312, and may have a thickness substantially the same as or similar to that of the first resistance pattern 312. The first alignment key 314 may include a metal and/or a metal silicide substantially the same as that of the first resistance pattern 312.

In an example embodiment, the first alignment key 314 may have a vertical cross-section of a “U” shape. Alternatively, the first alignment key 314 may have a vertical cross-section of a bar shape.

The first, third and fourth contact plugs 452, 450 and 454 and the shared contact plug 456 may include substantially the same material. That is, the first, third, fourth and fifth conductive layer patterns 442, 440, 444 and 446 may include substantially the same material, and the first, third, fourth and fifth barrier layer patterns 432, 430, 434 and 436 may include substantially the same material.

The semiconductor device may further include first and second wirings 482 and 480, a second insulating interlayer 490 and a protection layer 495.

In example embodiments, the first wiring 482 may include a sixth conductive layer pattern 462 and a sixth barrier layer pattern 472 surrounding a bottom and a sidewall of the sixth conductive layer pattern 462. The sixth conductive layer pattern 462 may include a metal, a metal nitride and/or a metal silicide, and the sixth barrier layer pattern 472 may include a metal or a metal nitride.

The second wiring 480 may include a seventh conductive layer pattern 460 and a seventh barrier layer pattern 470 surrounding a bottom and a sidewall of the seventh conductive layer pattern 460. The seventh conductive layer pattern 460 may include a metal, a metal nitride and/or a metal silicide, and the seventh barrier layer pattern 470 may include a metal or a metal nitride.

In an example embodiment, the first wiring 482 may be electrically connected to the first contact plug 452, and the second wiring 480 may be electrically connected to the third, fourth and shared contact plugs 450, 454 and 456. However, the first and second wirings 482 and 480 may have other electrical connections, and other wirings (not shown) may be further formed.

The second insulating interlayer 490 may be formed on the first insulating interlayer 340 to cover sidewalls of the wirings 482 and 480, and the protection layer may be formed on the second insulating interlayer 490 and the wirings 482 and 480. The second insulating interlayer 490 and the protection layer 495 may include an insulating material.

As illustrated above, the semiconductor in accordance with example embodiments may include the first resistance pattern 312 having a top surface lower than a top surface of the first insulating interlayer 340, i.e., the first resistance pattern 312 of which a top surface may be covered by the first insulating interlayer 340, and thus the first resistance pattern 312 may be protected by the first insulating interlayer 340 when the contact plugs 452, 450, 454 and 456 may be formed. Accordingly, the first resistance pattern 312 may have good electrical characteristics, and the semiconductor device including the first resistance pattern 312 may also have good electrical characteristics.

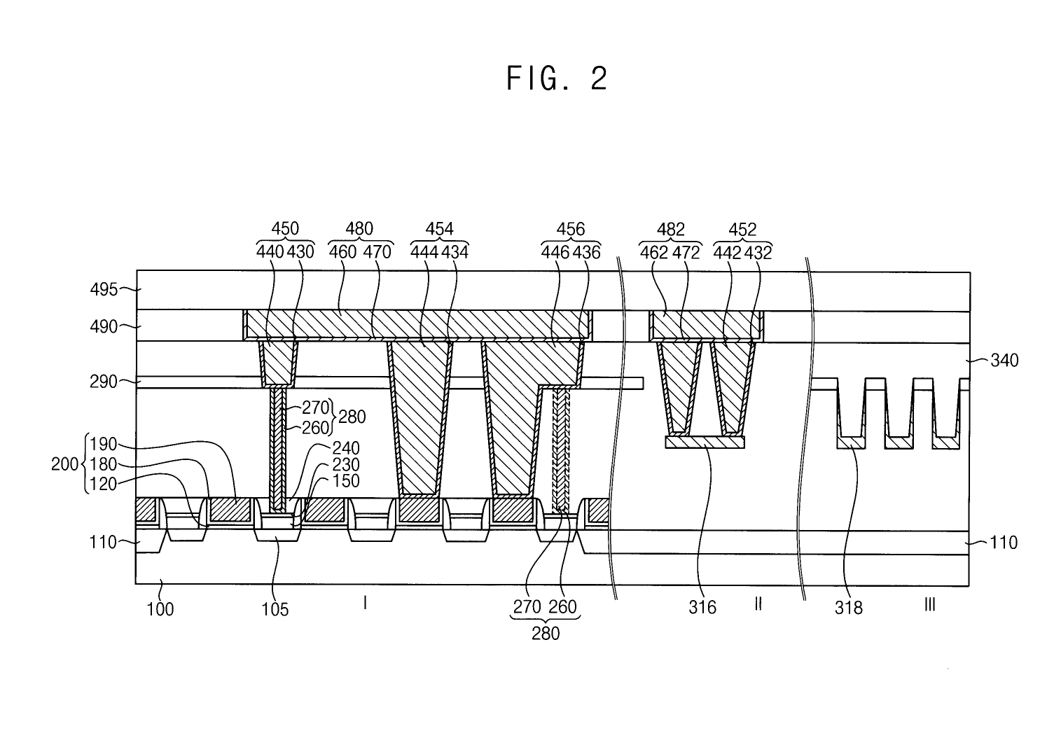

FIG. 2 is a cross-sectional view illustrating a semiconductor device in accordance with example embodiments. This semiconductor device may be substantially the same as that of FIG. 1 except that the semiconductor device may include a second resistance pattern 316 and a second alignment key 318 instead of the first resistance pattern 312 and the first alignment key 314. Thus, only the second resistance pattern 316 and the second alignment key 318 may be explained herein.

Referring to FIG. 2, the second resistance pattern 316 may be formed in the first insulating interlayer 340 in the resistance region of the logic region II like the first resistance pattern 312, and may have a top surface lower than the top surface of the first insulating interlayer 340. That is, at least a portion of the top surface of the second resistance pattern 316 may be covered by the first insulating interlayer 340. However, a bottom surface of the second resistance pattern 316 may be higher than the top surface of the gate structure 200 unlike the first resistance pattern 312.

The second alignment key 318 may be formed in the first insulating interlayer 340 in the scribe lane region III like the first alignment key 314. In example embodiments, the second alignment key 318 may have a bottom surface coplanar with the bottom surface of the second resistance pattern 316, and may have a thickness substantially the same as or similar to that of the second resistance pattern 316. Thus, the bottom surface of the second alignment key 318 may be higher than the top surface of the gate structure 200. The second alignment key 318 may include a metal and/or a metal silicide substantially the same as that of the first resistance pattern 312.

As illustrated above, only the thicknesses or the heights of the second resistance pattern 316 and the second alignment key 318 may be different from those of the first resistance pattern 312 and the first alignment key 314, respectively, and thus only a semiconductor device having the first resistance pattern 312 and the first alignment key 314 may be illustrated for the convenience of explanation, hereinafter.

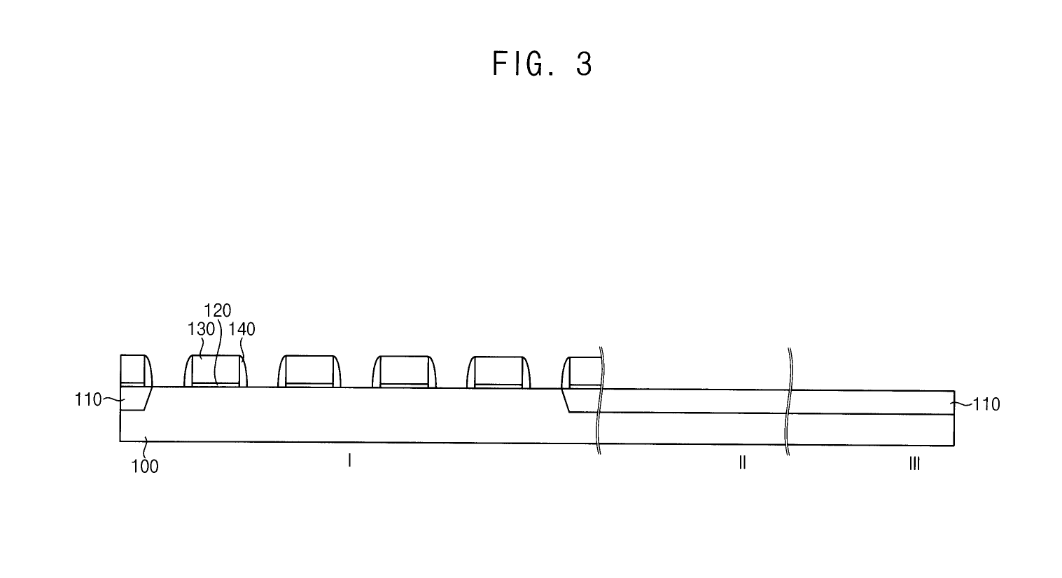

FIGS. 3 to 19 are cross-sectional views illustrating stages of a method of manufacturing a semiconductor device in accordance with example embodiments. This method may be applied to manufacture the semiconductor device of FIG. 1, however, it may not be limited thereto.

Referring to FIG. 3, an isolation layer 110 may be formed on a substrate 100, and a plurality of dummy gate structures and a plurality of gate spacers 140 may be formed on the substrate 100 and the isolation layer 110.

The substrate 100 may be divided into a field region in which the isolation layer 110 is formed and an active region in which the isolation layer 110 is not formed. In example embodiments, the isolation layer 110 may be formed by a shallow trench isolation (STI) process.

The substrate 100 may include a cell region I in which memory cells may be formed, a logic region II in which peripheral circuits for driving the memory cells and a resistance pattern may be formed, and a scribe lane region III in which alignment keys for aligning devices and/or chips may be formed. The logic region II may include a peripheral circuit region for the peripheral circuits and a resistance region for the resistance pattern, and only the resistance region is illustrated in FIGS. 3 to 19 for the convenience of explanation.

Each of the dummy gate structures may be formed by sequentially stacking a low-k dielectric layer pattern 120 and a dummy gate electrode 130 on the substrate 100 and the isolation layer 110.

Particularly, a low-k dielectric layer and a dummy gate electrode layer may be sequentially formed on the substrate 100 having the isolation layer 110 thereon. In example embodiments, the low-k dielectric layer may be formed by a chemical vapor deposition (CVD) process using silicon oxide. The dummy gate electrode layer may be formed by a CVD process using polysilicon, amorphous silicon, etc. The dummy gate electrode layer and the low-k dielectric layer may be patterned by a photolithography process to form the dummy gate structures each of which may include the low-k dielectric layer pattern 120 and the dummy gate electrode 130 sequentially stacked on the cell region I of the substrate 100.

A gate spacer layer covering the dummy gate structures may be formed on the isolation layer 110 and the substrate 100 and patterned by an anisotropic etching process to form the gate spacers 140 on sidewalls of the dummy gate structures. In example embodiments, the gate spacer layer may be formed using silicon nitride.

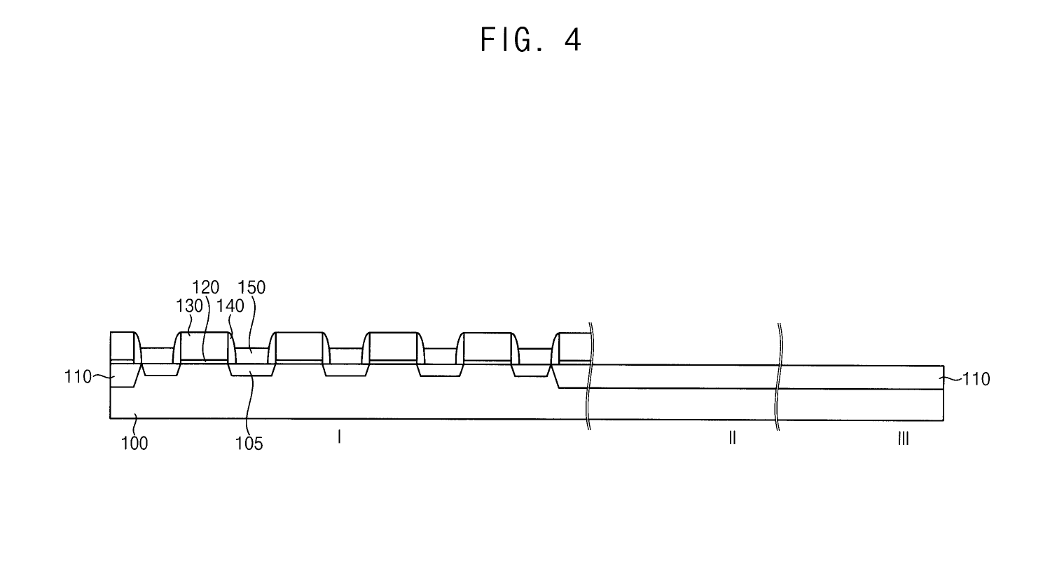

Referring to FIG. 4, impurity regions 105 may be formed at upper portions of the active region of the substrate 100 adjacent to the dummy gate structures, and an ESD layers 150 may be formed on the impurity regions 105.

Particularly, the active region of the substrate 100 may be partially removed using the dummy gate structures and the gate spacers 140 as an etching mask to form first trenches (not shown) at upper portions of the active region. The first trenches may be filled with the impurity regions 105.

In example embodiments, a first selective epitaxial growth (SEG) process may be performed using top surfaces of the substrate 100 exposed by the first trenches as a seed layer to form the first impurity regions 105. In an example embodiment, the first SEG process may be performed at a temperature of about 500° C. to about 900° C. under a pressure of about 0.1 Torr to a normal pressure.

The first SEG process may be performed using, e.g., dichlorosilane (SiH₂Cl₂) gas or germane (GeH₄) gas as a source gas, and thus a single crystalline silicon-germanium layer may be formed. In example embodiments, p-type impurity source gas, e.g., diborane (B₂H₆) gas may be also used to form a single crystalline silicon-germanium layer doped with p-type impurities.

In example embodiments, the first SEG process may be performed using disilane (Si₂H₆) gas and monomethylsilane (SiH₃CH₃) gas as a source gas to form a single crystalline silicon carbide layer. In example embodiments, n-type impurity source gas, e.g., phosphine (PH₃) gas may be also used to form a single crystalline silicon carbide layer doped with n-type impurities.

In example embodiments, in the first SEG process, the single crystalline silicon-germanium layer doped with p-type impurities and the single crystalline silicon carbide layer doped with n-type impurities may be sequentially formed, and thus the impurity regions 105 of both of a PMOS transistor and an NMOS transistor may be formed.

A second SEG process may be performed to form ESD layers on the impurity regions 105. The second SEG process may be performed using the impurity regions 105 as a seed layer. In an example embodiment, the second SEG process may be performed at a temperature of about 500° C. to about 900° C. under a pressure of about 0.1 Torr to a normal pressure. The second SEG process may be performed using p-type impurity source gas, e.g., dichlorosilane (SiH₂Cl₂) gas or diborane (B₂H₆) gas as a source gas, and thus a single crystalline silicon layer doped with p-type impurities may be formed. Alternatively, the second SEG process may be performed using n-type impurity source gas, e.g., dichlorosilane (SiH₂Cl₂) gas or phosphine (PH₃) gas as a source gas, and thus a single crystalline silicon layer doped with n-type impurities may be formed.

In example embodiments, the first SEG process for forming the impurity regions 105 and the second SEG process for forming the ESD layers 150 may be performed in-situ. That is, when the impurity regions 105 may be formed, a silicon source gas, a germanium source gas and a p-type impurity source gas may be provided to perform an SEG process, and providing the germanium source gas may be stopped to form the ESD layers 150. Alternatively, when the impurity regions 105 may be formed, a silicon source gas, a carbon source gas and an n-type impurity source gas may be provided to perform an SEG process, and providing the carbon source gas may be stopped to form the ESD layers 150.

In an example embodiment, the formation of the ESD layers 150 may be omitted.

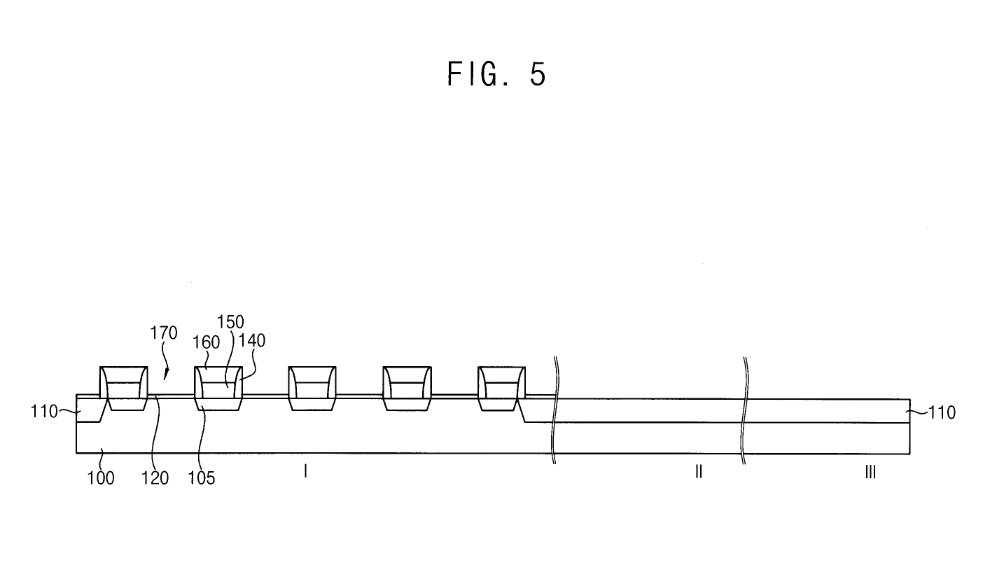

Referring to FIG. 5, a first insulation layer 160 covering the dummy gate structures and the gate spacers 140 may be formed on the substrate 100, the isolation layer 110 and the ESD layers 150. In example embodiments, the first insulation layer 160 may be formed using silicon oxide. Portions of the first insulation layer 160 in the logic region II and the scribe lane region III may be removed, and an upper portion of the first insulation layer 160 may be planarized until top surfaces of the dummy gate electrodes 130 may be exposed. In example embodiments, the planarization process may be performed by a chemical mechanical polishing (CMP) process.

The exposed dummy gate electrodes 130 may be removed to form recesses 170, and the low-k dielectric layer patterns 120 may be exposed. In an example embodiment, the low-k dielectric layer patterns 120 may be also removed together with the dummy gate electrodes 130. The dummy gate electrodes 130 may be removed by a wet etching processor a dry etching process.

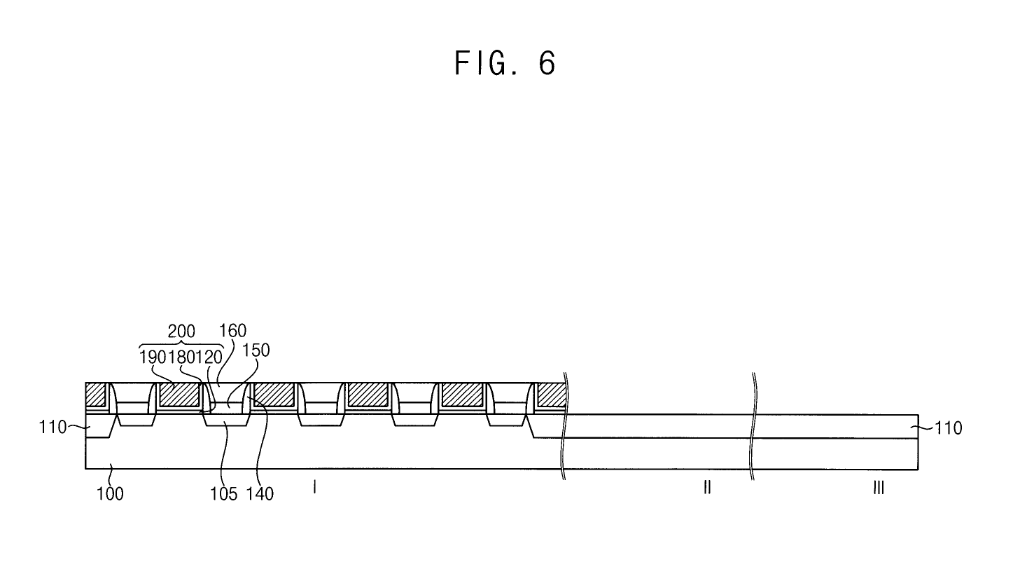

Referring to FIG. 6, a high-k dielectric layer pattern 180 may be formed on an inner wall of each recess 170, and a gate electrode 190 filling a remaining portion of each recess 170 may be formed.

Particularly, a high-k dielectric layer may be formed on the inner wall of the recess 170 a top surface of the first insulation layer 160 and a top surface of the isolation layer 110, and a gate electrode layer sufficiently filling a remaining portion of the recess 170 may be formed on the high-k dielectric layer.

The high-k dielectric layer may be formed by depositing a metal oxide. The metal oxide may include, e.g., hafnium oxide, tantalum oxide, zirconium oxide, etc. The gate electrode layer may be formed using a low resistance metal, e.g., aluminum, copper, etc., by an atomic layer deposition (ALD) process, a physical vapor deposition (PVD) process, etc. In an example embodiment, a heat treatment process, e.g., a rapid thermal annealing (RTA) process, a spike rapid thermal annealing (spike RTA) process, a flash rapid thermal annealing (flash RTA) process or a laser annealing process may be further performed.

Portions of the gate electrode layer and the high-k dielectric layer in the logic region II and the scribe lane region III may be removed and upper portions of the gate electrode layer and the high-k dielectric layer may be planarized to form the high-k dielectric layer pattern 180 on the inner wall of the recess 170 and the gate electrode 190 filling the remaining portion of the recess 170. In example embodiments, the planarization process may be performed by a CMP process.

Thus, a plurality of gate structures 200 each of which may include the low-k dielectric layer pattern 120, the high-k dielectric layer pattern 180 and the gate electrode 190 may be formed, and the gate spacers 140 may be formed on sidewalls of the gate structures 200.

Each gate structure 200, and the impurity regions 105 and the ESD layers 150 adjacent to the gate structure 200 may form a transistor.

In example embodiments, the semiconductor device may be a SRAM device, and the transistor may be a drive transistor, a load transistor or an access transistor of the SRAM device.

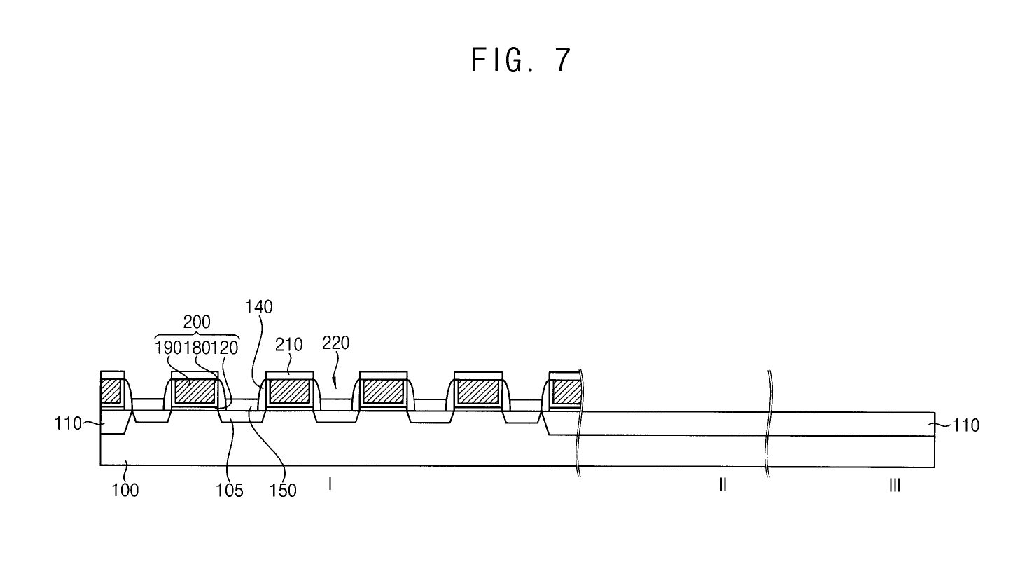

Referring to FIG. 7, a capping layer pattern 210 covering the gate structure 200 may be formed, and the first insulation layer 160 may be removed using the capping layer pattern 210 as an etching mask to form first openings 220 exposing the ESD layers 150. In an example embodiment, the capping layer pattern 210 may be formed not only on the gate structures 200 but also on a portion of the first insulation layer 160. In this case, the first insulation layer 160 may be partially removed and partially remain.

The capping layer pattern 210 may be formed by forming a capping layer on the gate structures 200, the first insulation layer 160 and the isolation layer 110 and patterning the capping layer. In example embodiments, the capping layer may be formed using a material having a high etching selectivity with respect to the first insulation layer 160, e.g., silicon nitride.

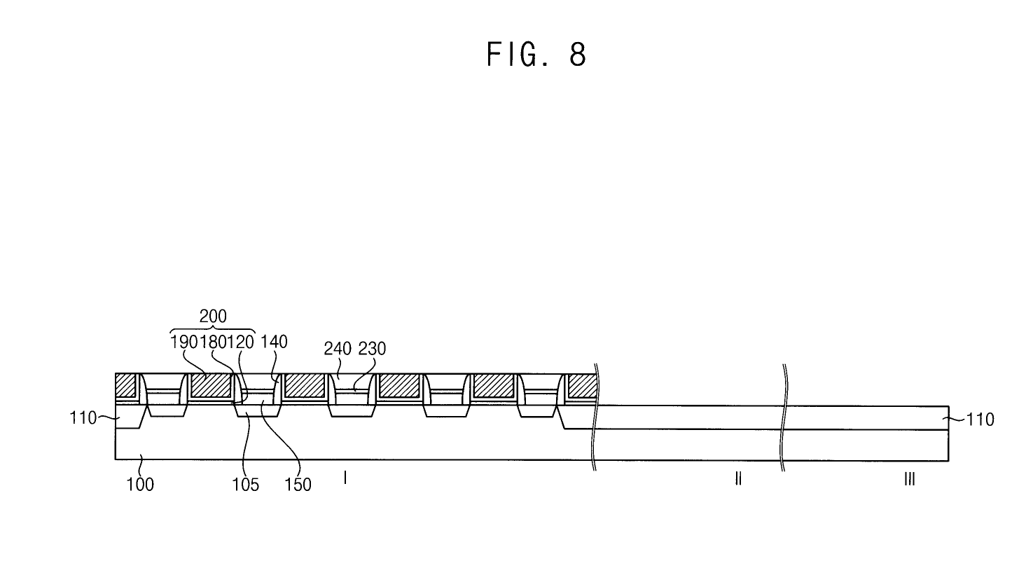

Referring to FIG. 8, metal silicide patterns 230 may be formed on the exposed ESD layers 150.

Particularly, a metal layer may be formed on the ESD layers 150, the gate spacers 140, the capping layer pattern 210 and the isolation layer 110, and thermally treated to form a metal silicide layer on the ESD layers 150 including silicon. A portion of the metal layer that is not reacted with the ESD layers 150 may be removed to form the metal silicide patterns 230 on the ESD layers 150 exposed by the first openings 220. In example embodiments, the metal layer may be formed using nickel, cobalt, platinum, etc., and thus the metal silicide patterns 230 may include nickel silicide, cobalt silicide, platinum silicide, etc.

A second insulation layer 240 filling a remaining portion of the first openings 220 may be formed.

That is, an insulation layer may be formed on the metal silicide patterns 230, the gate spacers 140, the capping layer pattern 210 and the isolation layer 110 to sufficiently fill the remaining portion of the first openings 220, and the insulation layer may be planarized until a top surface of the capping layer pattern 210 may be exposed to form the second insulation layer 240. In example embodiments, the second insulation layer 240 may be formed using a material substantially the same as that of the first insulation layer 160, e.g., silicon oxide, and thus the first and second insulation layers 160 and 240 may be merged.

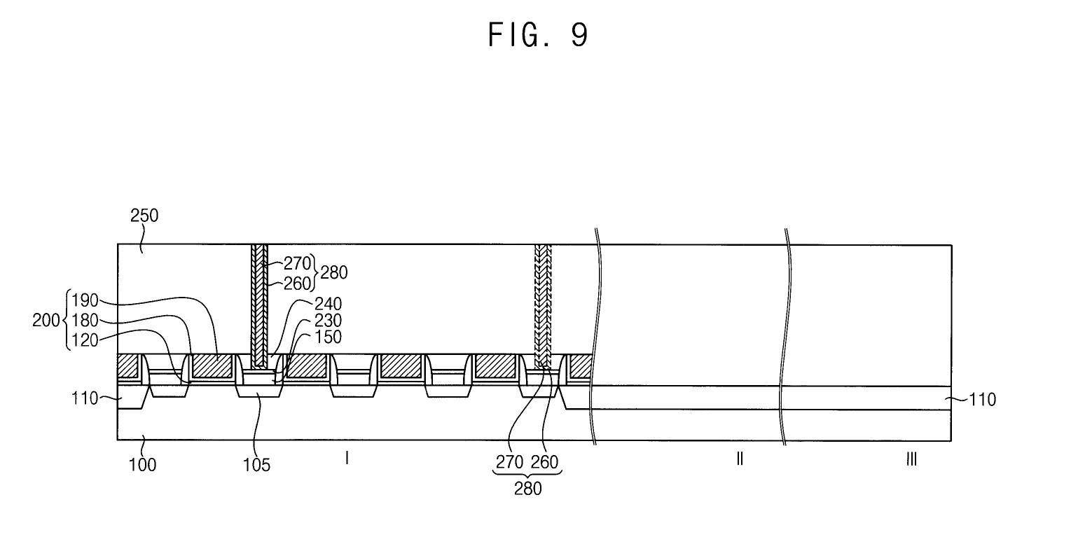

The planarization process may be performed until a top surface of the gate electrode 190 may be exposed, and thus the capping layer pattern 210 may be removed. However, when a second contact plug 280 (refer to FIG. 9) is formed self-aligned to the gate structures 200 and the gate spacers 140, the planarization process may be performed only until the capping layer pattern 210 may be exposed so that the capping layer pattern 210 may remain. Hereinafter, only the case in which the capping layer pattern 210 is removed may be illustrated.

Referring to FIG. 9, a first insulating interlayer 250 may be formed on the substrate 100 to cover the gate structures 200, the gate spacers 140 and the insulation layers 160 and 240.

In example embodiments, the first insulating interlayer 250 may be formed by a CVD process using silicon oxide.

The first insulating interlayer 250 and the second insulation layer 240 may be partially removed to form a second opening (not shown) exposing at least one of the metal silicide patterns 230, and the second contact plug 280 filling the second opening may be formed.

The second contact plug 280 may be formed by forming a second barrier layer on the exposed metal silicide pattern 230 and the first insulating interlayer 250 and forming a second conductive layer sufficiently filling a remaining portion of the second opening on the second barrier layer, and by planarizing upper portions of the second conductive layer and the second barrier layer until a top surface of the first insulating interlayer 250 may be exposed.

In example embodiments, the second barrier layer may be formed using a metal or a metal nitride, and the second conductive layer may be formed using doped polysilicon, a metal, a metal nitride and/or a metal silicide.

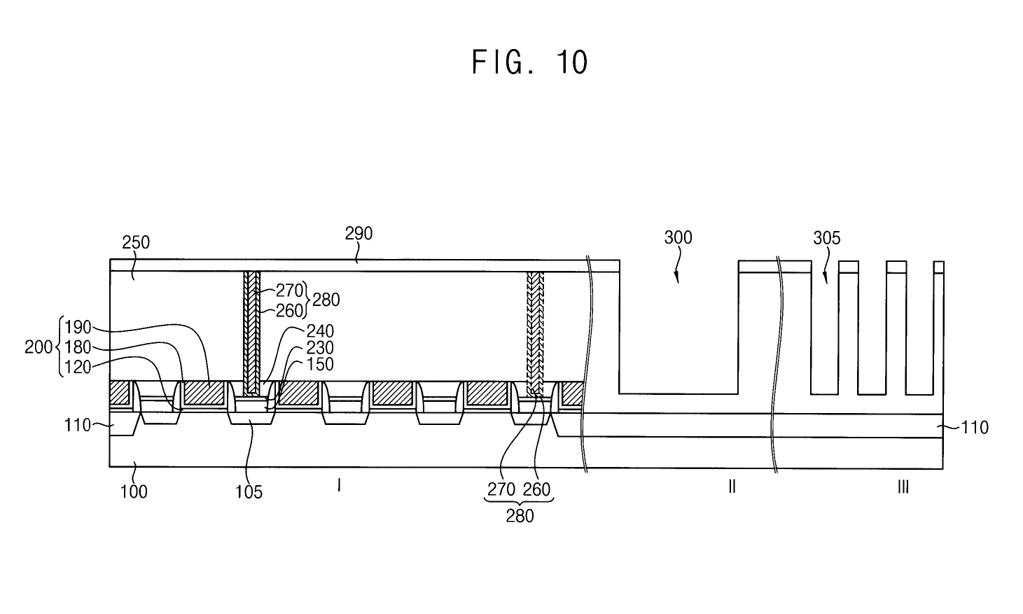

Referring to FIG. 10, an etch stop layer 290 may be formed on the first insulating interlayer 250, and upper portions of the etch stop layer 290 and the first insulating interlayer 250 in the logic region II and the scribe lane region III may be partially removed to form a second trench 300 and a first alignment key recess 305, respectively.

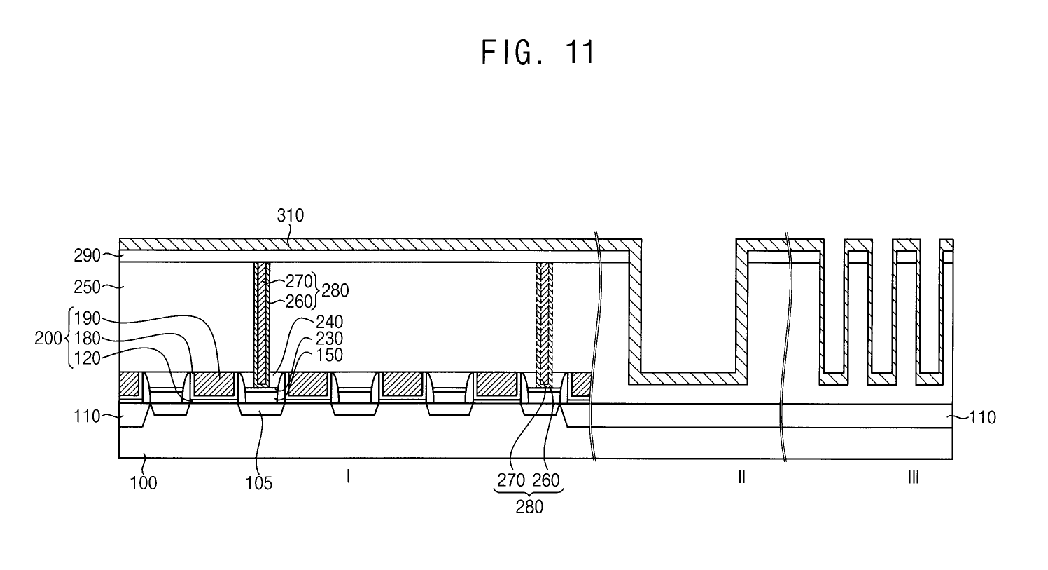

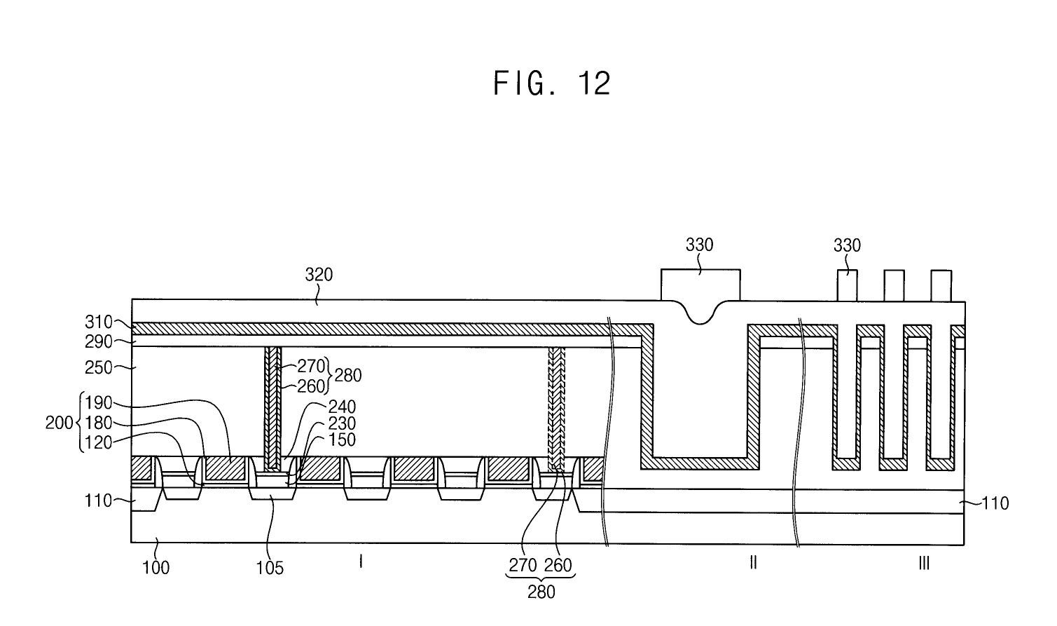

In example embodiments, the second trench 300 and the first alignment key recess 305 may be formed to have a depth greater than a thickness of a resistance layer 310 (refer to FIG. 11) subsequently formed. Thus, a top surface of the resistance layer 310, which may be formed on the second trench 300 and the first alignment key recess 305, may be lower than a top surface of the first insulating interlayer 250. The first alignment key recess 305 may be formed to have a depth sufficiently deep for aligning a first photoresist pattern 330 (refer to FIG. 12) that may serve as an etching mask for patterning the resistance layer 310. In example embodiments, the second trench 300 and the first alignment key recess 305 may be formed to have a depth substantially the same as each other.

In an example embodiment, the second trench 300 and the first alignment key recess 305 may be formed to have bottom surfaces lower than top surfaces of the gate structures 200. In an example embodiment, the second trench 300 and the first alignment key recess 305 may be formed to a depth equal to or more than about 200 Å.

Referring to FIG. 11, the resistance layer 310 may be formed on the etch stop layer 290 and the first insulating interlayer 250 having the second trench 300 and the first alignment key recess 305 thereon.

In example embodiments, the resistance layer 310 may be formed using a metal, e.g., tungsten, having a resistance higher than that of the gate electrode 190. The resistance layer 310 may further include silicon, and the resistance layer 310 may have a resistance varying according to the concentration of silicon in the resistance layer 310.

Referring to FIG. 12, a third insulation layer 320 sufficiently filling the second trench 300 and the first alignment key recess 305 may be formed on the resistance layer 310, and the first photoresist pattern 330 partially covering the second trench 300 and the first alignment key recess 305 may be formed on the third insulation layer 320.

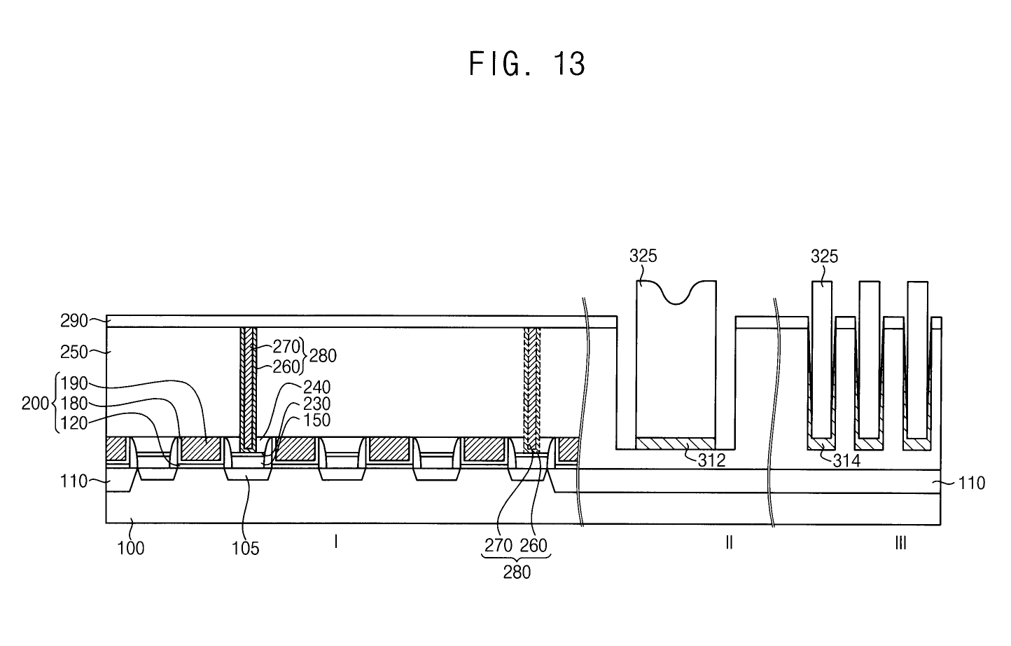

The third insulation layer 320 may prevent a top surface of the first resistance pattern 312 (refer to FIG. 13) from being oxidizing when the first photoresist pattern 330 may be removed after forming the first resistance pattern 312, and in an example embodiment, the formation of the third insulation layer 320 may be omitted. In example embodiments, the third insulation layer 320 may be formed using a material substantially the same as that of the first insulating interlayer 250, e.g., silicon oxide.

In example embodiments, the first photoresist pattern 330 may be formed to cover a central portion of the second trench 300 and a central portion of the first alignment key recess 305. Particularly, a photoresist layer may be formed on the third insulation layer 320, and the photoresist layer may be patterned to form the first photoresist pattern 330. During the formation of the first photoresist pattern 330, a depth difference or a height difference between a portion of the resistance layer 310 on a bottom surface of the first alignment key recess 305 and a portion of the resistance layer 310 on a top surface of the etch stop layer 290 may be detected. Thus, the location of the first photoresist pattern 330 may be determined using the region in which the depth difference or the height difference may be detected as an alignment key.

Referring to FIG. 13, the third insulation layer 320 and the resistance layer 310 may be patterned using the first photoresist pattern 330 as an etching mask to form a third insulation layer pattern 325, and a first resistance pattern 312 and a first alignment key 314, respectively.

In example embodiments, the first resistance pattern 312 may be formed on a central portion of the bottom surface of the second trench 300, and the first alignment key 314 may be formed on a bottom surface of the first alignment key recess 305. The resistance layer 310 may remain on a sidewall of the first alignment key recess 305, and thus the first alignment key 314 may have a vertical cross-section of a “U” shape.

The first photoresist pattern 330 may be removed. In example embodiments, the first photoresist pattern 330 may be removed by an ashing process and/or a stripping process using oxygen. The third insulation layer pattern 325 may remain on the first resistance pattern 312 and the first alignment key 314, however, in an example embodiment, the third insulation layer pattern 325 may be removed to expose the first resistance pattern 312 and the first alignment key recess 314.

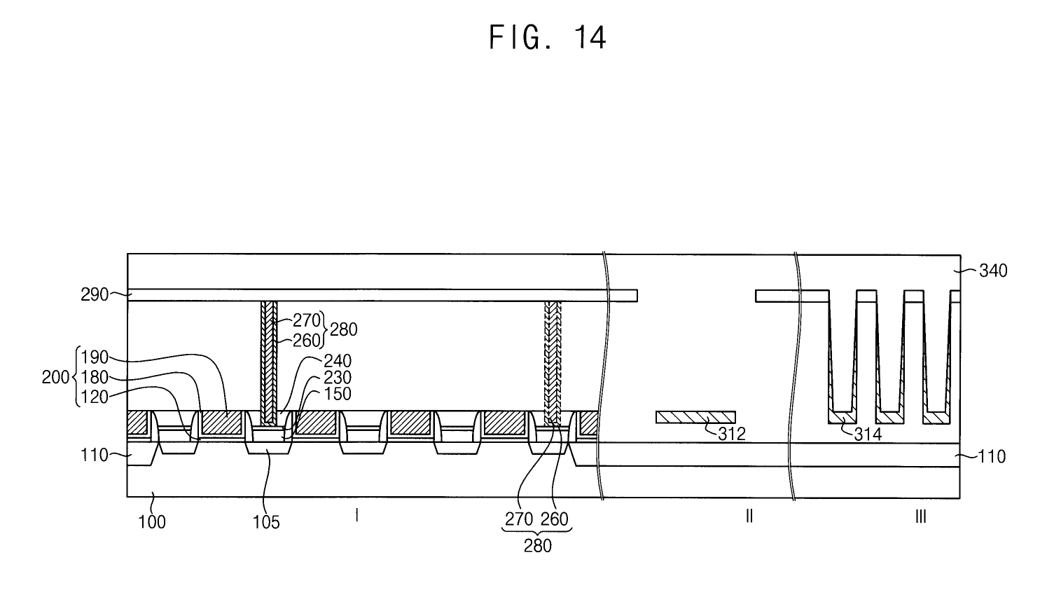

Referring to FIG. 14, a fourth insulation layer sufficiently covering the second trench 300 and having a top surface higher than a top surface of the third insulation layer pattern 325 may be formed on the etch stop layer 290, the third insulation layer pattern 325 and the first insulating interlayer 250.

In example embodiments, the fourth insulation layer may be formed using a material substantially the same as that of the third insulation layer pattern 325 and the first insulating interlayer 250, and thus the first insulating interlayer 250, the third insulation layer pattern 325 and the fourth insulation layer may be merged. Hereinafter, the merged layer may be referred to as a first insulating interlayer 340.

As described above, when the third insulation layer pattern 325 has been removed before forming the fourth insulation layer, the fourth insulation layer may be formed to a thickness sufficiently filling remaining portions of the second trench 300 and the first alignment key recess 305 on the exposed first resistance pattern 312 and the exposed first alignment key 314. In this case, the fourth insulation layer and the first insulating interlayer 250 may be also merged, and the merged layer may be also referred to as the first insulating interlayer 340.

A planarization process for planarizing an upper portion of the first insulating interlayer 340, e.g., a CMP process may be further performed.

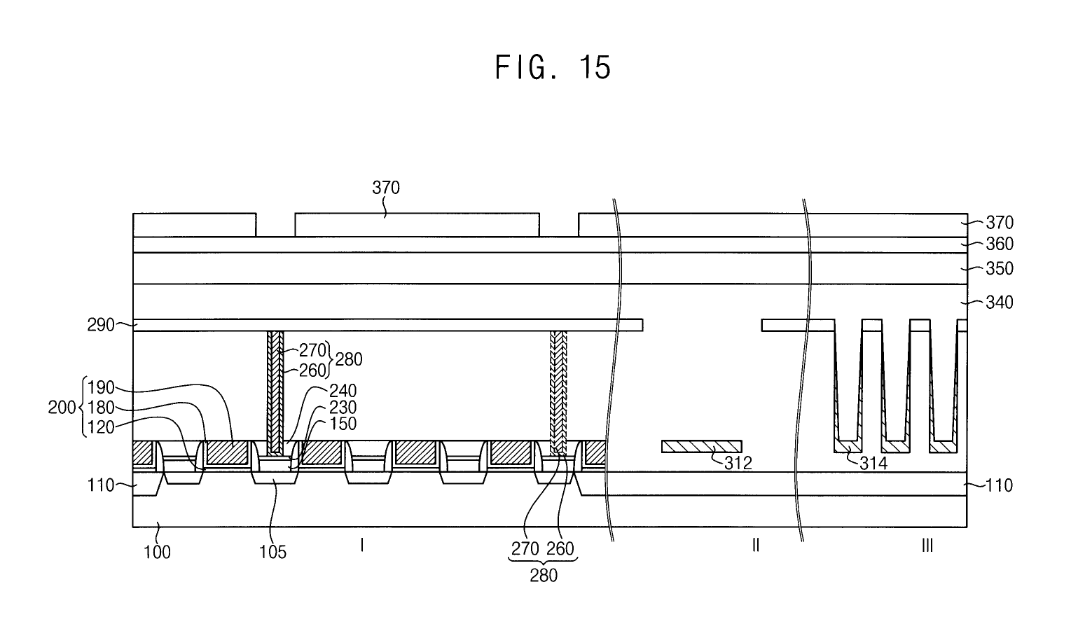

Referring to FIG. 15, a first hard mask layer and a second photoresist pattern 370 may be formed on the first insulating interlayer 340.

In example embodiments, a first spin on hard mask (SOH) layer 350 and a first silicon oxynitride layer 360 may be sequentially formed as the first hard mask layer.

The second photoresist pattern 370 may be formed not to overlap at least one second contact plug 280.

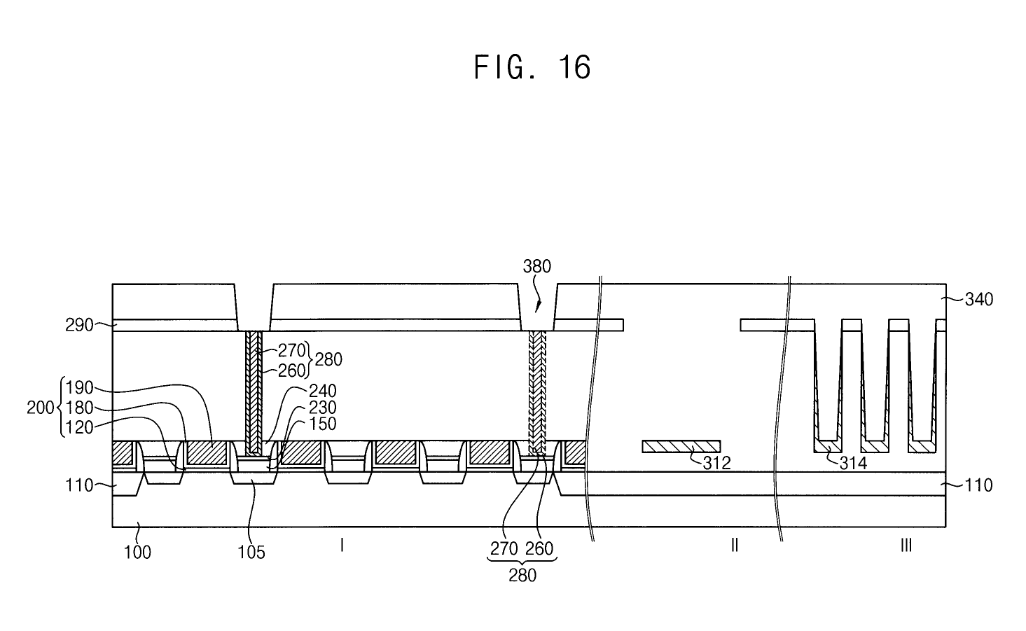

Referring to FIG. 16, the first hard mask layer may be patterned using the second photoresist pattern 370 as an etching mask, and the first insulating interlayer 340 and the etch stop layer 290 may be partially removed using the patterned first hard mask layer as an etching mask to form a third opening 380 exposing a top surface of the second contact plug 280.

The second photoresist pattern 370 and the first hard mask layer may be removed.

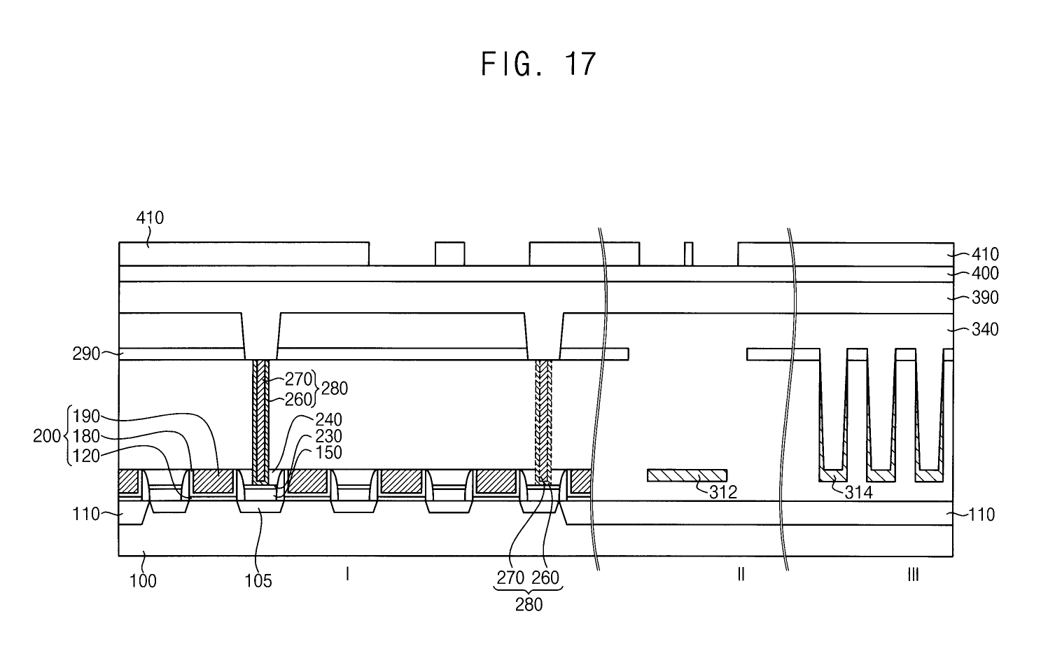

Referring to FIG. 17, a second hard mask layer filling the third opening 380 may be formed on the exposed second contact plug 280 and the first insulating interlayer 340, and a third photoresist pattern 410 may be formed on the second hard mask layer.

In example embodiments, a second SOH layer 390 and a second silicon oxynitride layer 400 may be sequentially formed as the second hard mask layer.

The third photoresist pattern 410 may be formed not to overlap at least one of the gate structures 200 or at least a portion of the first resistance pattern 312. In example embodiments, the third photoresist pattern 410 may be formed not to overlap at least one of the gate structures 200 adjacent to the second contact plug 280.

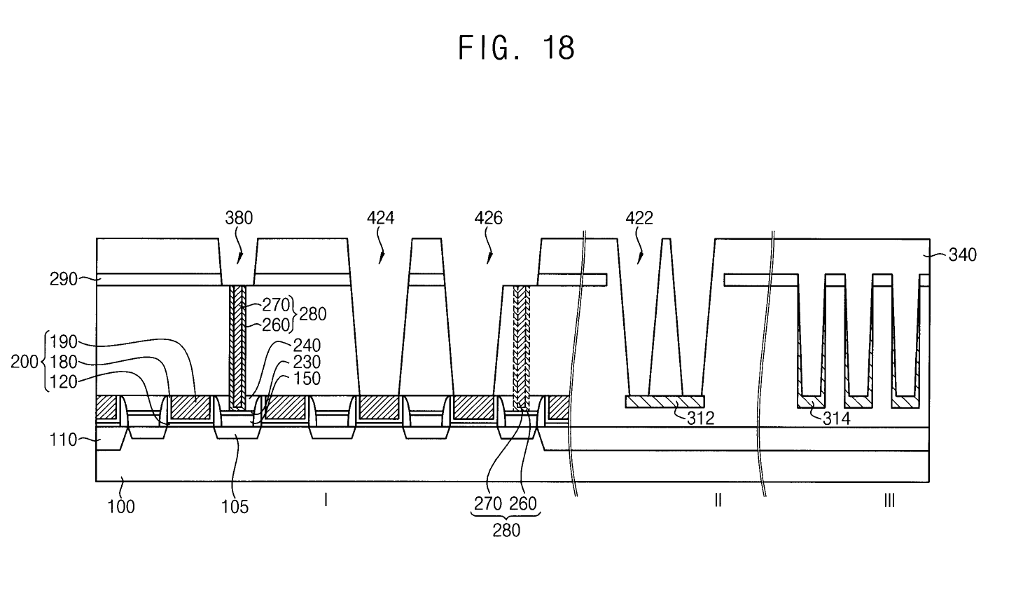

Referring to FIG. 18, the second hard mask layer may be patterned using the third photoresist pattern 410 as an etching mask, and the first insulating interlayer 340 and the etch stop layer 290 may be partially removed using the patterned second hard mask layer as an etching stop layer to form a fourth opening 422 exposing the first resistance pattern 312 and fifth and sixth openings 424 and 426 exposing top surfaces of the gate structures 200.

The third photoresist pattern 410 and the second hard mask layer may be removed, and thus the third opening 380 exposing the second contact plug 280 may be formed again. A sixth opening 426 adjacent to the second contact plug 280 and a third opening 380 exposing a top surface of the second contact plug 280 may be in fluid communication with each other to define one opening, which may be referred to as the sixth opening 426.

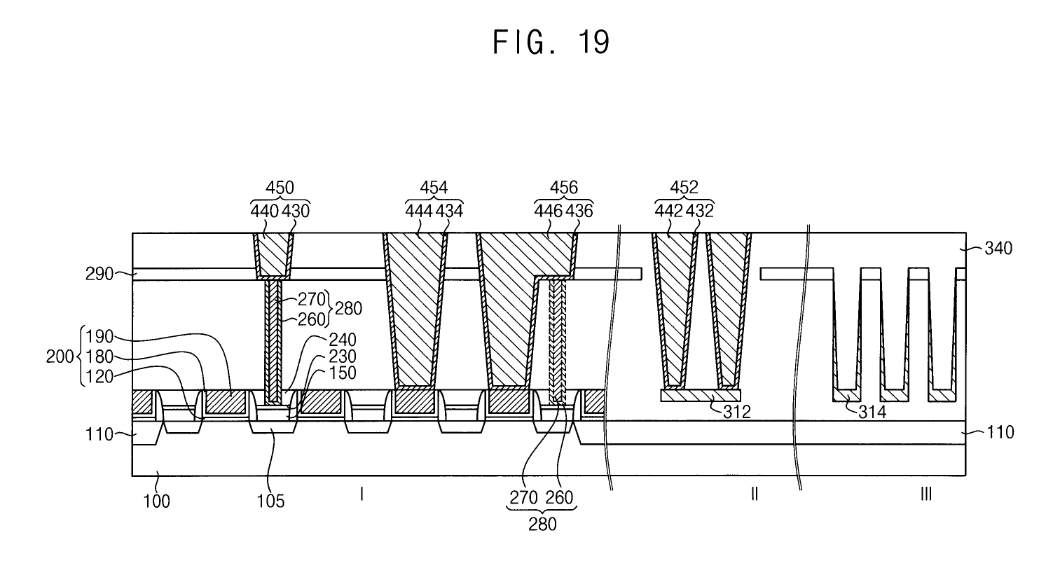

Referring to FIG. 19, first, third and fourth contact plugs 452, 450 and 454 and a shared contact plug 456 filling the fourth, third, fifth, and sixth openings 422, 380, 424 and 426, respectively, may be formed on the exposed first resistance pattern 312, the exposed second contact plug 280, and the exposed gate structures 200, respectively.

Particularly, after a first barrier layer may be formed on the exposed first resistance pattern 312, the exposed gate structures 200, the exposed second contact plug 280 and sidewalls of the third to sixth openings 380, 422, 424 and 426, a first conductive layer sufficiently filling the third to sixth openings 380, 422, 424 and 426 may be formed on the first barrier layer, and upper portions of the first conductive layer and the first barrier layer may be planarized until a top surface of the first insulating interlayer 340 may be exposed. In example embodiments, the first barrier layer may be formed using a metal or a metal nitride, and the first conductive layer may be formed using a metal, a metal nitride and/or a metal silicide.

In example embodiments, the planarization process may be performed by a CMP process. The first resistance pattern 312 may have a top surface lower than that of the first insulating interlayer 340, and thus the first resistance pattern 312 may not be damaged during the planarization process. Thus, the CMP process may have a sufficient process margin and the first resistance pattern 312 may have good electrical characteristics.

Accordingly, the first contact plug 452 making direct contact with the top surface of the first resistance pattern 312 and filling the fourth opening 422 may be formed, the third contact plug 450 making direct contact with the top surface of the second contact plug 280 and filling the third opening 380 may be formed, the fourth contact plug 454 making direct contact with the top surface of the gate structure 200 and filling the fifth opening 424 may be formed, and the shared contact plug 456 making direct contact with the top surfaces of both of the gate structure 200 and the second contact plug 280 and filling the sixth opening 426 may be formed.

The first contact plug 452 may be formed to include a first conductive layer pattern 442 and a first barrier layer pattern 432 surrounding a bottom and a sidewall of the first conductive layer pattern 442. The third contact plug 450 may be formed to include a third conductive layer pattern 440 and a third barrier layer pattern 430 surrounding a bottom and a sidewall of the third conductive layer pattern 440. The fourth contact plug 454 may be formed to include a fourth conductive layer pattern 444 and a fourth barrier layer pattern 434 surrounding a bottom and a sidewall of the fourth conductive layer pattern 444. The shared contact plug 456 may be formed to include a fifth conductive layer pattern 446 and a fifth barrier layer pattern 436 surrounding a bottom and a sidewall of the fifth conductive layer pattern 446.

Referring to FIG. 1 again, a second insulating interlayer 490 may be formed on the first insulating interlayer 340 and the contact plugs 452, 450, 454 and 456, and wirings 482 and 480 may be formed through the second insulating interlayer 490 to be electrically connected to the contact plugs 452, 450, 454 and 456.

In example embodiments, the second insulating interlayer 490 may be partially removed to form seventh openings (not shown) exposing the contact plugs 452, 450, 454 and 456, and a third barrier layer may be formed on the exposed contact plugs 452, 450, 454 and 456, sidewalls of the seventh openings and the insulating interlayers 340 and 490. Further, a third conductive layer sufficiently filling the seventh openings may be formed on the third barrier layer, and the third conductive layer and the third barrier layer may be planarized until a top surface of the second insulating interlayer 490 may be exposed to form the first and second wirings 482 and 480. The third barrier layer may be formed using a metal or a metal nitride, and the third conductive layer may be formed using a metal, a metal nitride and/or a metal silicide.

In an example embodiment, the first wiring 482 may be formed to be electrically connected to the first contact plug 452, and the second wiring 480 may be formed to be electrically connected to the third, fourth and shared contact plugs 450, 454 and 456. However, other types of electrical connections may be also possible.

A protection layer 495 may be formed on the second insulating interlayer 490 and the wirings 482 and 480 using an insulating material.

As illustrated above, the second trench 300 and the first alignment key recess 305 may be formed on the first insulating interlayer 250 and the resistance layer 310 may be formed therein, so that the resistance layer 310 may be exactly patterned by detecting the depth difference or the height difference between a portion of the resistance layer 310 on a bottom surface of the first alignment key recess 305 and a portion of the resistance layer 310 on a top surface of the first insulating interlayer 250 according to the depth of the first alignment key recess 305. Further, the first resistance pattern 312 may have a top surface lower than that of the first insulating interlayer 340 and covered by the first insulating interlayer 340, so that a CMP process for forming the contact plugs 452, 450, 454 and 456 may have a large process margin and the first resistance pattern 312 may be prevented from being damaged.

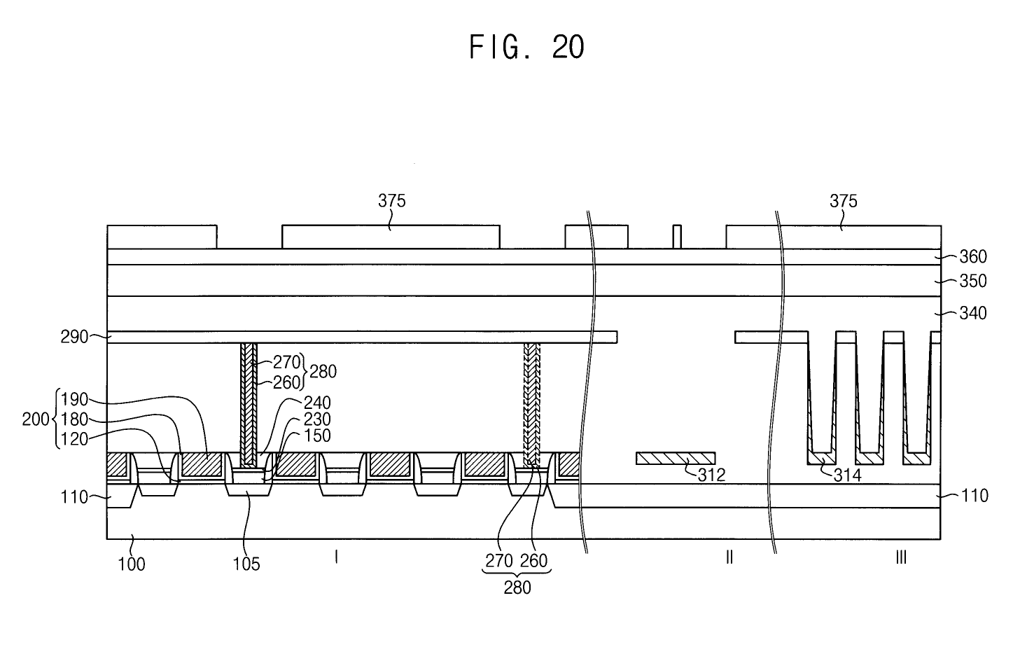

FIGS. 20 to 22 are cross-sectional views illustrating stages of a method of manufacturing a semiconductor device in accordance with example embodiments. This method may be substantially the same as or similar to that illustrated with reference to FIGS. 1 to 19 except for the order of forming the fourth opening 422. Thus, like reference numerals refer to like elements, and repetitive explanations are omitted herein.

First, processes substantially the same as or similar to those illustrated with reference to FIGS. 3 to 14 may be performed.

Referring to FIG. 20, a first SOH layer 350 and a first silicon oxynitride layer 360 serving as a first hard mask layer may be formed on the first insulating interlayer 340, and a fourth photoresist pattern 375 may be formed on the first hard mask layer.

The fourth photoresist pattern 375 may be formed not to overlap at least one of the second contact plug 280 or at least a portion of the first resistance pattern 312.

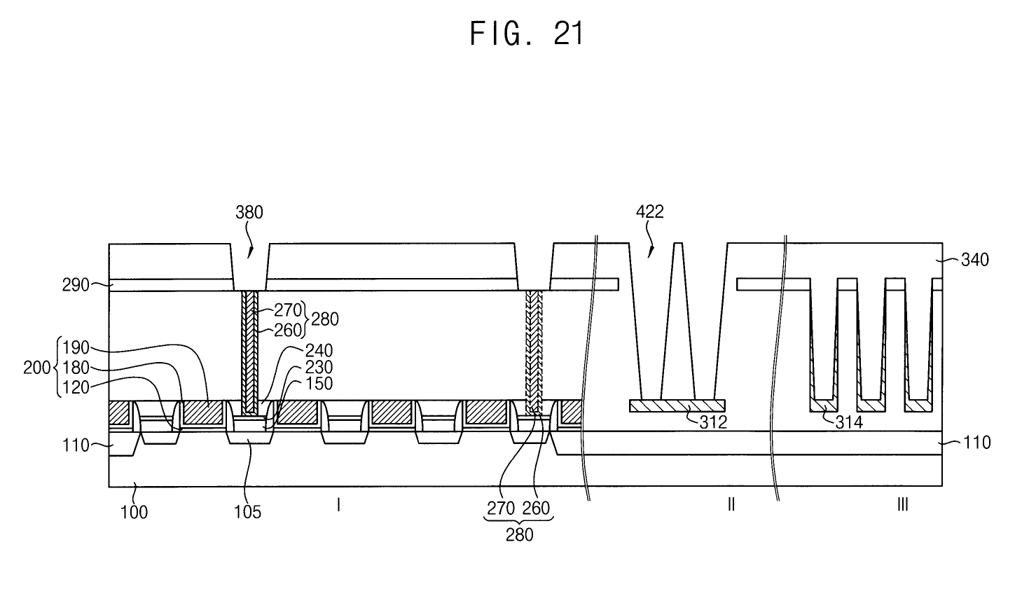

Referring to FIG. 21, the first hard mask layer may be patterned using the fourth photoresist pattern 375 as an etching mask, and the first insulating interlayer 340 and the etch stop layer 290 may be partially removed using the patterned first hard mask layer as an etching mask to form a third opening 380 exposing a top surface of the second contact plug 280 and a fourth opening 422 exposing a top surface of the first resistance pattern 312.

The fourth photoresist pattern 375 and the first hard mask layer may be removed.

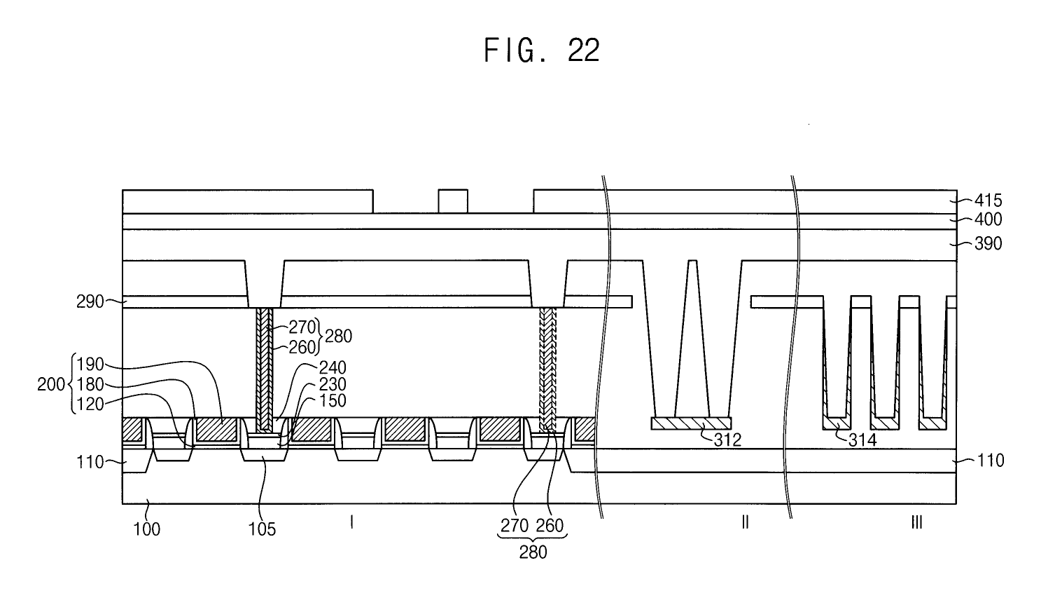

Referring to FIG. 22, a second SOH layer 390 and a second silicon oxynitride layer 400 serving as a second hard mask layer filling the third and fourth openings 380 and 422 may be formed on the exposed second contact plug 280, the exposed first resistance pattern 312 and the first insulating interlayer 340, and a fifth photoresist pattern 415 may be formed on the second hard mask layer.

The fifth photoresist pattern 415 may be formed not to overlap at lease one of the gate structures 200. In example embodiments, the fifth photoresist pattern 415 may be formed not to overlap at least a gate structure 200 adjacent to the second contact plug 280.

Processes substantially the same as or similar to those illustrated with reference to FIGS. 19 and 1 may be performed to manufacture the semiconductor device.

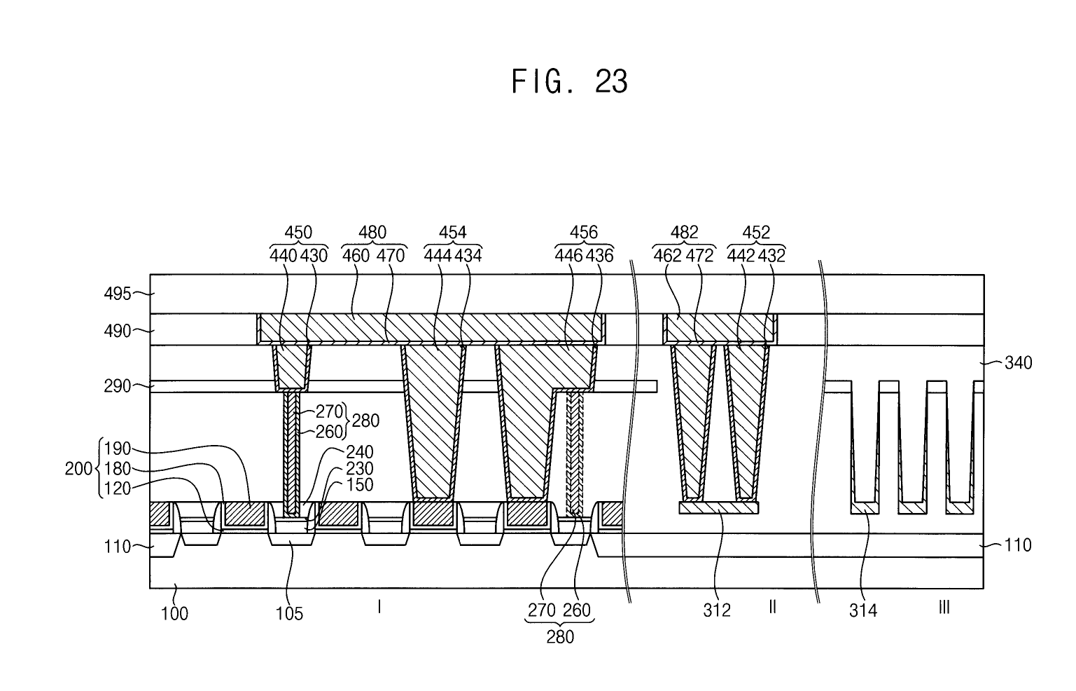

FIG. 23 is a cross-sectional view illustrating a semiconductor device in accordance with example embodiments. This semiconductor device may be substantially the same as or similar to that of FIG. 1 except that the semiconductor device may not have an alignment key in the scribe lane region III. Thus, like reference numerals refer to like elements, and repetitive explanations are omitted herein.

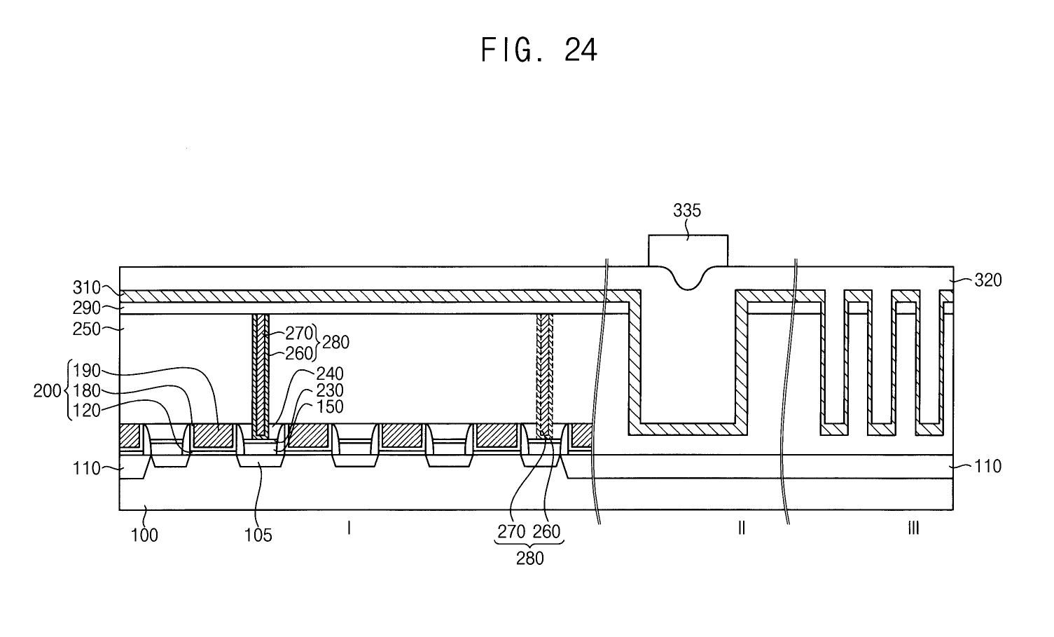

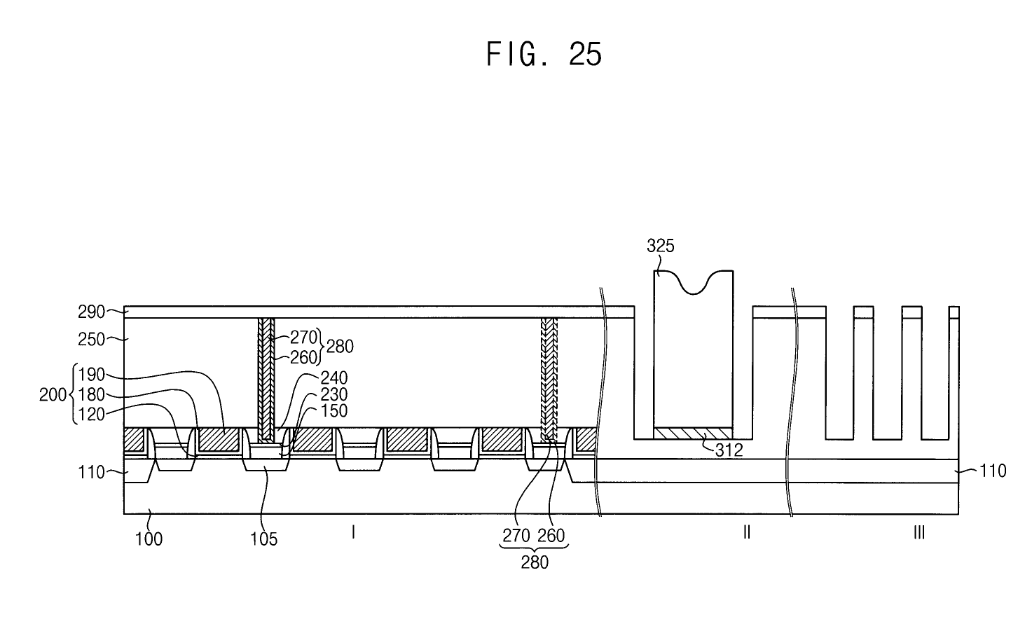

FIGS. 24 and 25 are cross-sectional views illustrating stages of a method of manufacturing a semiconductor device in accordance with example embodiments. This method may be substantially the same as or similar to that illustrated with reference to FIGS. 1 to 19 except for a sixth photoresist pattern 335. Thus, like reference numerals refer to like elements, and repetitive explanations are omitted herein.

First, processes substantially the same as or similar to those illustrated with reference to FIGS. 1 to 11 may be performed.

Referring to FIG. 24, a third insulation layer 320 sufficiently filling the second trench 300 and the first alignment key recess 305 may be formed, and the sixth photoresist pattern 335 may be formed on the third insulation layer 320.

In example embodiments, the sixth photoresist pattern 335 may be formed to cover only a central portion of the second trench 300. That is, the sixth photoresist pattern 335 may not cover any portion of the first alignment key recess 305 unlike the first photoresist pattern 330. Particularly, after forming a photoresist layer on the third insulation layer 320, and the photoresist layer may be patterned to form the sixth photoresist pattern 335. During the patterning process, a depth difference or a height difference between a portion of the resistance layer 310 on a bottom surface of the first alignment key recess 305 and a portion of the resistance layer 310 on the etch stop layer 290 may be detected, and the location of the sixth photoresist pattern 335 may be determined using a region in which the depth difference may be detected as an alignment key.

Referring to FIG. 25, the third insulation layer 320 and the resistance layer 310 may be patterned using the sixth photoresist pattern 335 as an etching mask to form a third insulation layer pattern 325 and a first resistance pattern 312, respectively.

In example embodiments, the first resistance pattern 312 may be formed on a central bottom surface of the second trench 300 and no alignment key may be formed unlike the semiconductor device of FIGS. 1 to 19. The portion of the resistance layer 310 in the first alignment key recess 305 has been used for aligning the sixth photoresist pattern 335, and thus the alignment key may not be necessarily formed by patterning the resistance layer 310.

The sixth photoresist pattern 335 may be removed.

Processes substantially the same as or similar to those illustrated with reference to FIGS. 14 to 19 and 1 may be performed to manufacture the semiconductor device of FIG. 23.

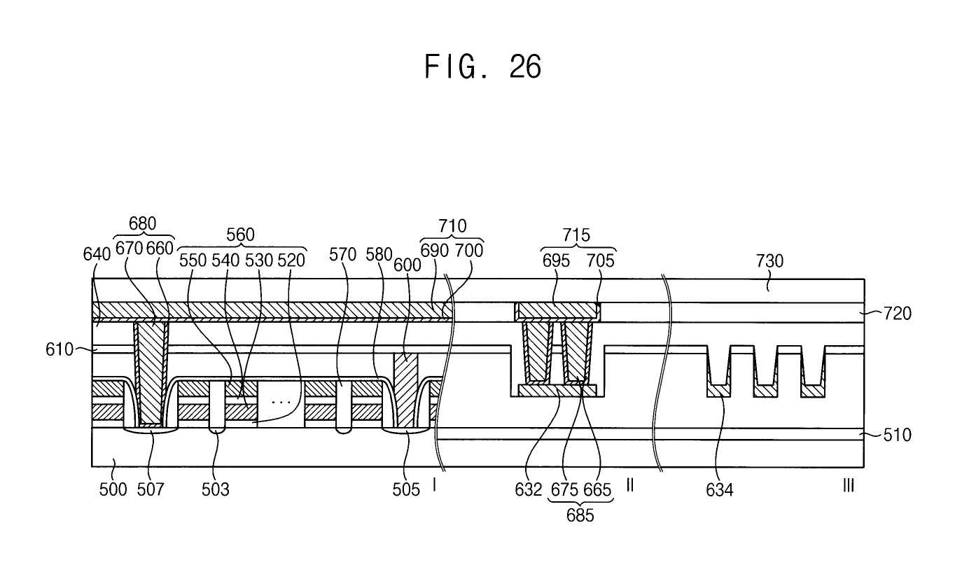

FIG. 26 is a cross-sectional view illustrating a semiconductor device in accordance with example embodiments.

Referring to FIG. 26, the semiconductor device may include a plurality of gate structures 560, a first insulating interlayer 640, a first resistance pattern 632 and a first contact plug 685 on a substrate 500. Additionally, the semiconductor device may include a second contact plug 680 and a first alignment key 634.

The substrate 500 may be a silicon substrate, a germanium substrate, a silicon-germanium substrate, an SOI substrate, a GOI substrate, etc. The substrate 500 may be divided into a field region in which an isolation layer 510 is formed and an active region in which no isolation layer is formed.

The substrate 500 may include a cell region I in which memory cells may be formed, a logic region II in which peripheral circuits for driving the memory cells and a resistance pattern may be formed, and a scribe lane region III in which alignment keys for aligning devices and/or chips may be formed. The logic region II may include a peripheral circuit region for the peripheral circuits and a resistance region for the resistance pattern, and only the resistance region is illustrated in FIG. 26 for the convenience of explanation. In example embodiments, the active region in the cell region I of the substrate 500 may extend in first direction parallel with a top surface of the substrate 500, and a plurality of active regions may be formed in a second direction substantially perpendicular to the first direction. In FIG. 26, only the active region in the cell region I may be illustrated.

Each gate structure 560 may include a tunnel insulation layer pattern 520, a floating gate 530, a dielectric layer pattern 540 and a control gate 550 sequentially stacked on the cell region I of the substrate 500. In example embodiments, a plurality of gate structures 560 may be formed in a first direction substantially parallel with a top surface of the substrate 500.

The tunnel insulation layer pattern 520 may include an oxide, e.g., silicon oxide, an oxynitride, e.g., silicon oxynitride, silicon oxide doped with polysilicon or a low-k dielectric material, and the floating gate 530 may include doped polysilicon or a metal having a high work function, e.g., tungsten, titanium, cobalt, nickel, etc. The dielectric layer pattern 540 may have a multi-layered structure, e.g., an oxide/nitride/oxide (ONO) structure, or a metal oxide having a high dielectric constant. The high-k metal oxide may include hafnium oxide, titanium oxide, tantalum oxide, zirconium oxide, aluminum oxide, etc. The control gate 550 may include doped polysilicon, a low resistance metal, e.g., aluminum, copper, etc., a metal nitride, a metal silicide, etc.

Alternatively, each gate structure 560 may include a charge trapping layer pattern (not shown), a blocking layer pattern (not shown) and a gate electrode (not shown), instead of the floating gate 530, the dielectric layer pattern 540 and the control gate 550, sequentially stacked on the tunnel insulation layer pattern 520.

The charge trapping layer pattern may include a nitride, e.g., silicon nitride or an oxide, e.g., hafnium oxide, and the blocking layer pattern may include silicon oxide or a metal oxide having a high dielectric constant, e.g., hafnium oxide, titanium oxide, tantalum oxide, zirconium oxide, aluminum oxide, etc. The gate electrode may include doped polysilicon, a low resistance metal, e.g., aluminum, copper, etc., a metal nitride, a metal silicide, etc.

Hereinafter, only the case in which the floating gate 530, the dielectric layer pattern 540 and the control gate 550 on the tunnel insulation layer pattern 520 is illustrated.

In example embodiments, the tunnel insulation layer patterns 520 may have an island shape from each other on the active region of the substrate 500, and the floating gates 530 may also have an island shape from each other thereon. Each of the dielectric layer patterns 540 and the control gates 550 may extend in a second direction substantially perpendicular to the first direction on the floating gates 530 and the isolation layer 510. Alternatively, the tunnel insulation layer patterns 520 may not have an island shape but extend in the first direction on the active region of the substrate 500.

First, second and third impurity regions 503, 505 and 507 may be formed at upper portions of the active region of the substrate 500 adjacent to the gate structures 560, and the gate structures 560 and the impurity regions 503, 505 and 507 may form transistors. In example embodiments, the semiconductor device may be a NAND flash memory device, and the transistors may be cell transistors thereof.

Spacers 570 may be formed on sidewalls of the gate structures 560, and protection layer pattern 580 may be formed on the gate structures 560 and the spacers 570. Spaces between the gate structures 560 that are spaced apart from each other at a relatively small distance may be filled with the spacers 570. In example embodiments, the spacers 570 and the protection layer pattern 580 may include a nitride, e.g., silicon nitride.

The first insulating interlayer 640 may cover the protection layer pattern 580 on the whole region of the substrate 500. In example embodiments, the first insulating interlayer 640 may include silicon oxide. The first insulating interlayer 640 may further include an etch stop layer 610 therein. In example embodiments, the etch stop layer 610 may include, e.g., silicon nitride.

The first resistance pattern 632 may be formed in the first insulating interlayer 640 in the resistance region of the logic region II and may have a top surface lower than that of the first insulating interlayer 640. That is, the top surface of the first resistance pattern 632 may be covered at least partially by the first insulating interlayer 640. In an example embodiment, the first resistance pattern 632 may have a bottom surface lower than a top surface of the gate structures 560.

The first resistance pattern 632 may include a metal and/or a metal silicide, which may be different from a metal or a metal silicide included in the control gate 550 of each gate structure 560, at least at an upper portion thereof. For example, the first resistance pattern 632 may include tungsten or tungsten silicide, which may have a resistance higher than that of the metal or the metal silicide included in the control gate 550 of each gate structure 560.

The first contact plug 685 may penetrate a portion of the first insulating interlayer 640 and make direct contact with a top surface of the first resistance pattern 632. Thus, the first contact plug 685 may make direct contact with an upper portion of the first resistance pattern 632 including a metal and/or a metal silicide. In example embodiments, the first contact plug 685 may have a top surface coplanar with a top surface of the first insulating interlayer 640.

In an example embodiment, the first contact plug 685 may include a first conductive layer pattern 675 and a first barrier layer pattern 665 surrounding a bottom and a sidewall of the first conductive layer pattern 675. The first conductive layer pattern 675 may include a metal, a metal nitride and/or a metal silicide, and the first barrier layer pattern 665 may include a metal or a metal nitride.

The second contact plug 680 may penetrate the first insulating interlayer 640 and make contact with a top surface of the third impurity region 507 to be electrically connected thereto. In example embodiments, the second contact plug 680 may be electrically connected to a bit line 710 on the first insulating interlayer 640 and serve as a bit line contact plug. The bit line 710 may include a third conductive layer pattern 690 and a third barrier layer pattern 700 surrounding a bottom and a sidewall of the third conductive layer pattern 690. The third conductive layer pattern 690 may include a metal, a metal nitride and/or a metal silicide, and the third barrier layer pattern 700 may include a metal or a metal nitride.

In an example embodiment, the second contact plug 680 may include a second conductive layer pattern 670 and a second barrier layer pattern 660 surrounding a bottom and a sidewall of the second conductive layer pattern 670. The second conductive layer pattern 670 may include a metal, a metal nitride and/or a metal silicide, and the second barrier layer pattern 660 may include a metal or a metal nitride.

The first and second contact plugs 685 and 680 may include substantially the same material. That is, the first and second conductive layer patterns 675 and 670 may include substantially the same material, and the first and second barrier layer patterns 665 and 660 may include substantially the same material.

The first alignment key 634 may be formed in the first insulating interlayer 640 in the scribe lane region III. In example embodiments, the first alignment key 634 may have a bottom surface coplanar with a bottom surface of the first resistance pattern 632 and have a thickness substantially the same as or similar to a thickness of the first resistance pattern 632. The first alignment key 634 may include a metal and/or a metal silicide substantially the same as that of the first resistance pattern 632.

In an example embodiment, the first alignment key 634 may have a vertical cross-section of a “U” shape. Alternatively, the first alignment key 634 may have a vertical cross-section of a bar shape of which a top surface may be parallel with a top surface of the substrate 500.

The semiconductor device may further include a wiring 715, a second insulating interlayer 720 and a protection layer 730.

The wiring 715 may include a fourth conductive layer pattern 695 and a fourth barrier layer pattern 705 surrounding a bottom and a sidewall of the fourth conductive layer pattern 695. The fourth conductive layer pattern 695 may include a metal, a metal nitride and/or a metal silicide, and the fourth barrier layer pattern 705 may include a metal or a metal nitride. In an example embodiment, the wiring 715 may be formed on the first insulating interlayer 640 and be electrically connected to the first contact plug 685.

The second insulating interlayer 720 may be formed on the first insulating interlayer 640 and cover sidewalls of the bit line 710 and the wiring 715, and the protection layer 730 may be formed on the second insulating interlayer 720, the bit line 710 and the wiring 715. The second insulating interlayer 720 and the protection layer 730 may include an insulating material.

The semiconductor device may further include a common source line (CSL) 600 electrically connected to the second impurity region 505. In example embodiments, the CSL 600 may penetrate a portion of the first insulating interlayer 640 and make contact with a bottom surface of the etch stop layer 610.

As illustrated above, the semiconductor device in accordance with example embodiments may include the first resistance pattern 632 having the top surface lower than that of the first insulating interlayer 640, that is, the first resistance pattern 632 of which the top surface may be covered by the first insulating interlayer 640. Thus, the first resistance pattern 632 may be protected by the first insulating interlayer 640 during the formation of the contact plugs 685 and 680. Accordingly, the first resistance pattern 632 may have good electrical characteristics, and the semiconductor device including the first resistance pattern 632 may also have good electrical characteristics.

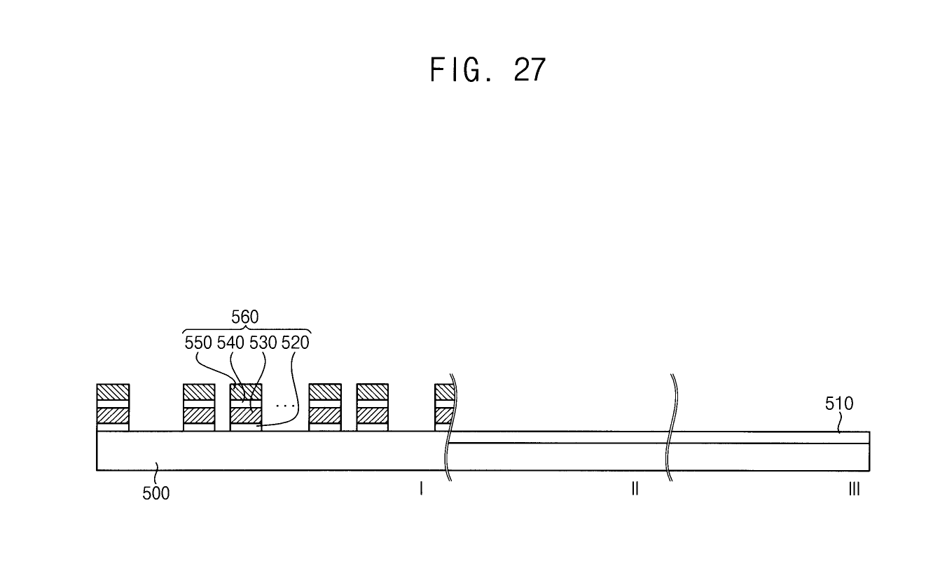

FIGS. 27 to 33 are cross-sectional views illustrating stages of a method of manufacturing a semiconductor device in accordance with example embodiments. This method may be applied to manufacture the semiconductor device of FIG. 26, however, it may not be limited thereto.

Referring to FIG. 27, a plurality of gate structures 560 may be formed on a substrate 500 having an isolation layer 510 thereon.

The substrate 500 may be divided into an active region and a field region by the isolation layer 510. The substrate 500 may include a cell region I in which memory cells may be formed, a logic region II in which peripheral circuits for driving the memory cells and a resistance pattern may be formed, and a scribe lane region III in which alignment keys for aligning devices and/or chips may be formed. The logic region II may include a peripheral circuit region for the peripheral circuits and a resistance region for the resistance pattern, and only the resistance region is illustrated in FIGS. 27 to 33 for the convenience of explanation. In example embodiments, the active region in the cell region I of the substrate 500 may extend in a first direction parallel with a top surface of the substrate 500, and a plurality of active regions may be formed in a second direction substantially perpendicular to the first direction. In FIGS. 27 to 33, only the active region in the cell region I may be illustrated.

Each gate structure 560 may be formed by sequentially forming and patterning a tunnel insulation layer, a floating gate layer, a dielectric layer and a control gate layer on the cell region I of the substrate 500. In an example embodiment, after forming a gate mask on the control gate layer, the control gate layer, the dielectric layer, the floating gate layer and the tunnel insulation layer may be patterned using the gate mask as an etching mask to form the gate structures 560. Thus, each gate structure 560 may be formed to include a tunnel insulation layer pattern 520, a floating gate 530, a dielectric layer pattern 540 and a control gate 550 sequentially stacked on the cell region I of the substrate 500. In example embodiments, a plurality of gate structures 560 may be formed in the first direction.

The tunnel insulation layer may be formed using an oxide, e.g., silicon oxide, an oxynitride, e.g., silicon oxynitride, silicon oxide doped with impurities or a low-k dielectric material, etc., and the floating gate layer may be formed using doped polysilicon, a metal having a high work function, e.g., tungsten, titanium, cobalt, nickel, etc. The dielectric layer may be formed using an oxide and/or a nitride to have an ONO structure or using a metal oxide having a high dielectric constant. The high-k metal oxide may include, e.g., hafnium oxide, titanium oxide, tantalum oxide, zirconium oxide, aluminum oxide, etc. The control gate layer may be formed using doped polysilicon, a low resistance metal, e.g., aluminum, copper, etc., a metal nitride, a metal silicide, etc.

Alternatively, each gate structure 560 may be formed to include a charge trapping layer pattern (not shown), a blocking layer pattern (not shown) and a gate electrode (not shown), instead of the floating gate 530, the dielectric layer pattern 540 and the control gate 550, sequentially stacked on the tunnel insulation layer pattern 520.

The charge trapping layer pattern may be formed using a nitride, e.g., silicon nitride or an oxide, e.g., hafnium oxide, and the blocking layer pattern may be formed using silicon oxide or a metal oxide having a high dielectric constant, e.g., hafnium oxide, titanium oxide, tantalum oxide, zirconium oxide, aluminum oxide, etc. The gate electrode may be formed using doped polysilicon, a low resistance metal, e.g., aluminum, copper, etc., a metal nitride, a metal silicide, etc.

Hereinafter, only the case in which the floating gate 530, the dielectric layer pattern 540 and the control gate 550 are formed on the tunnel insulation layer pattern 520 is illustrated.

In example embodiments, the tunnel insulation layer patterns 520 may be formed to have an island shape from each other on the active region of the substrate 500, and the floating gates 530 may be also formed to have an island shape from each other thereon. Each of the dielectric layer patterns 540 and the control gates 550 may be formed to extend in the second direction on the floating gates 530 and the isolation layer 510. Alternatively, the tunnel insulation layer patterns 520 may be formed not to have an island shape but to extend in the first direction on the active region of the substrate 500.

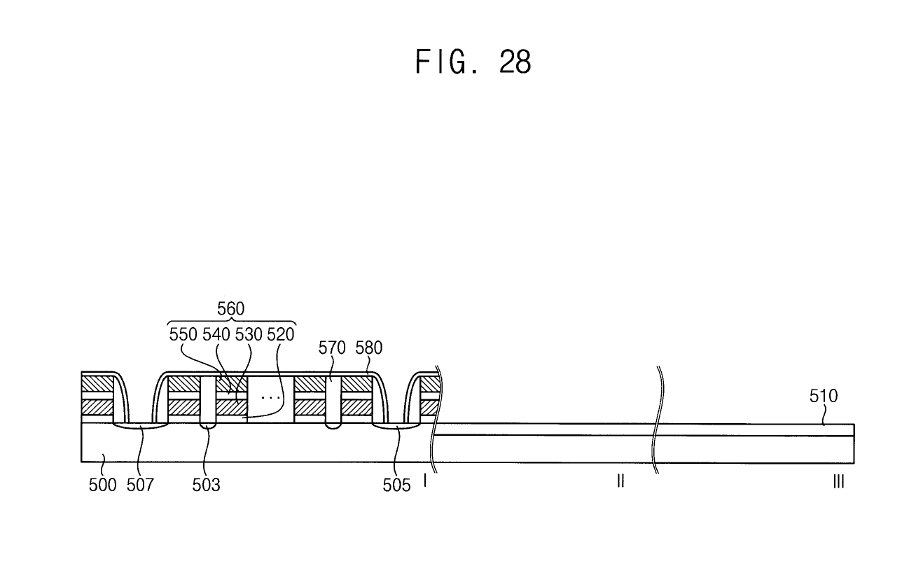

Referring to FIG. 28, an ion implantation process may be performed using the gate structures 560 as an ion implantation mask to form first, second and third impurity regions 503, 505 and 507 at upper portions of the active region of the substrate 500 adjacent to the gate structures 560.

A spacer layer may be formed on the substrate 500 to cover the gate structures 560. The spacer layer may be formed using a nitride, e.g., silicon nitride by a CVD process, an ALD process, a sputtering process, etc. The spacer layer may be etched by an anisotropic etching process to form spacers 570 on sidewalls of the gate structures 560. Spaces between the gate structures 560 spaced apart from each other at a relatively small distance may be filled with the spacers 570.

A protection layer may be formed on the spacers 570 and the gate structures 560. The protection layer may be formed using a nitride, e.g., silicon nitride by a CVD process, an ALD process, a sputtering process, etc. The protection layer may be partially etched by an anisotropic process to form a protection layer pattern 580.

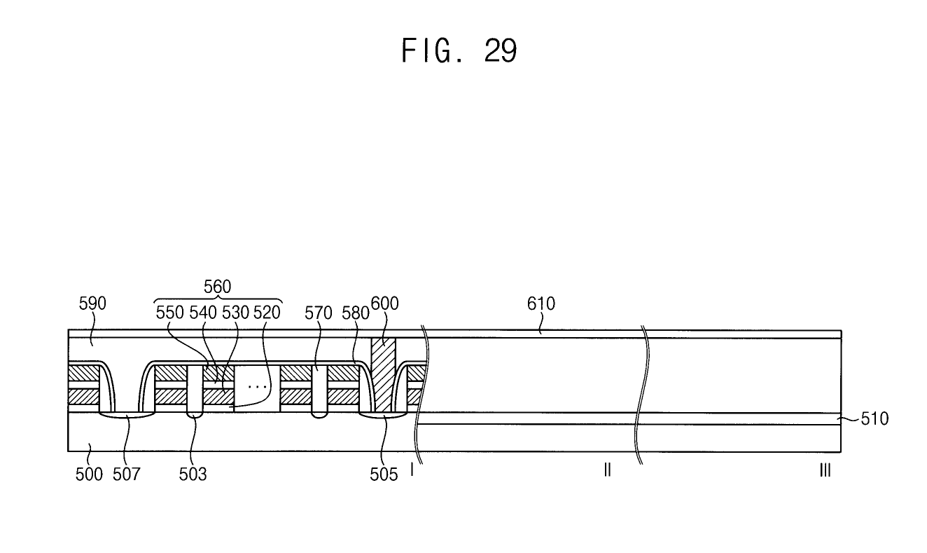

Referring to FIG. 29, a first insulating interlayer 590 covering the protection layer pattern 580 may be formed on the substrate 500. The first insulating interlayer 590 may be formed using silicon oxide, e.g., borophosphosil Gate glass (BPSG), undoped silicate glass (USG), spin-on glass (SOG), etc., by a chemical vapor deposition (CVD) process, an ALD process, a sputtering process, etc.

A first opening (not shown) may be formed through the first insulating interlayer 590 to expose the second impurity region 505, and a first conductive layer filling the first opening may be formed on the exposed second impurity region 505 and the first insulating interlayer 590. The first conductive layer may be formed using doped polysilicon, a metal or a metal silicide. The first conductive layer may be planarized until the first insulating interlayer 590 may be exposed to form a CSL 600 filling the first opening and making contact with the second impurity region 505.

An etch stop layer 610 may be formed on the first insulating interlayer 590 and the CSL 600. In example embodiments, the etch stop layer 610 may be formed using, e.g., silicon nitride.

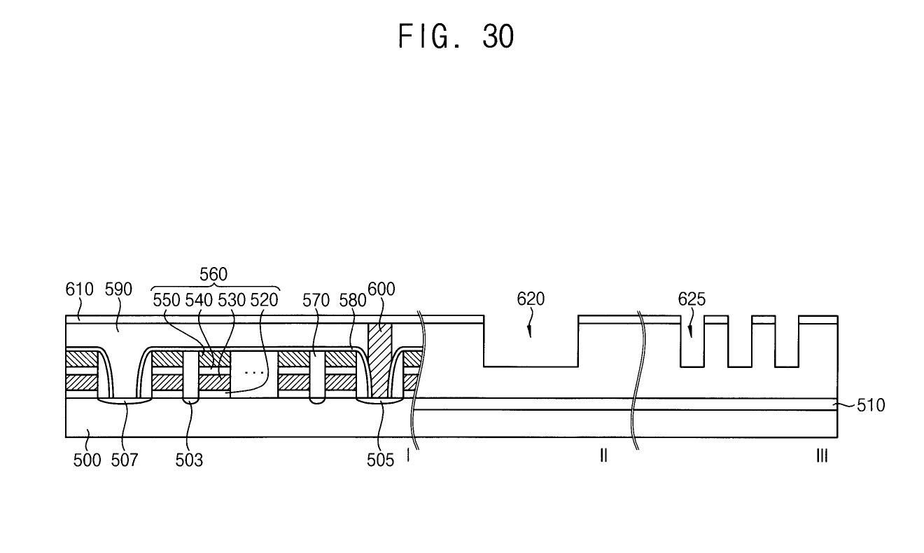

Referring to FIG. 30, processes substantially the same as or similar to those illustrated with reference to FIG. 10 may be performed.

Particularly, upper portions of the etch stop layer 610 and the first insulating interlayer 590 in the logic region II and the scribe lane region III may be partially etched to form a trench 620 and a first alignment key recess 625.

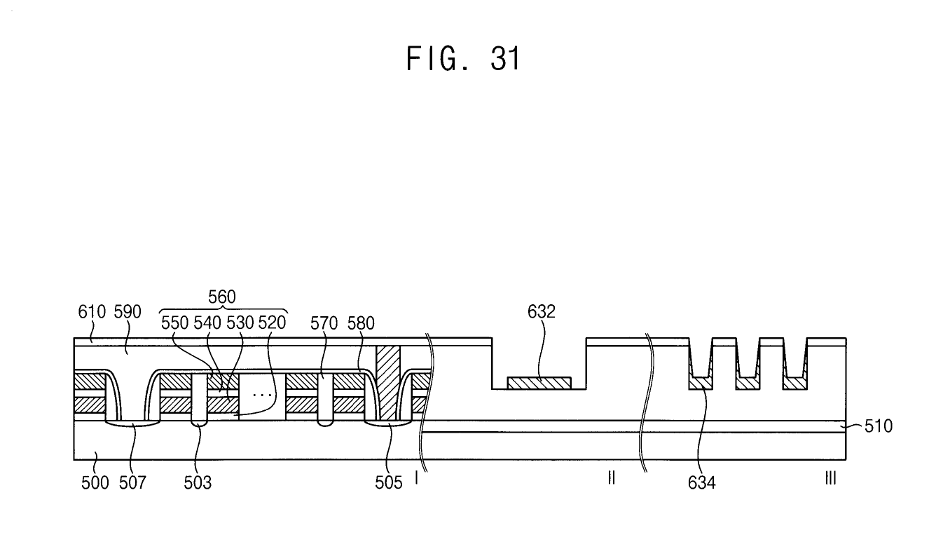

Referring to FIG. 31, processes substantially the same as or similar to those illustrated with reference to FIG. 10 may be performed.

Particularly, a resistance layer may be formed on the first insulating interlayer 590 having the trench 620 and the first alignment key recess 625 thereon using, e.g., tungsten or tungsten silicide, and a third insulation layer (not shown) may be formed on the first insulating interlayer 590 to sufficiently fill the trench 620 and the first alignment key recess 625. A first photoresist pattern (not shown) partially covering the trench 620 and the first alignment key recess 625 may be formed on the third insulation layer. The first photoresist pattern may be formed to cover a central portion of the trench 620 and a central portion of the first alignment key recess 625.

The third insulation layer and the resistance layer may be patterned using the first photoresist pattern as an etching mask to form a third insulation layer pattern (not shown), and a first resistance pattern 632 and a first alignment key recess 625, respectively.

The first photoresist pattern may be removed, and the third insulation layer pattern may remain on the first resistance pattern 632 and the first alignment key recess 625 or removed to expose the first resistance pattern 632 and the first alignment key 634.

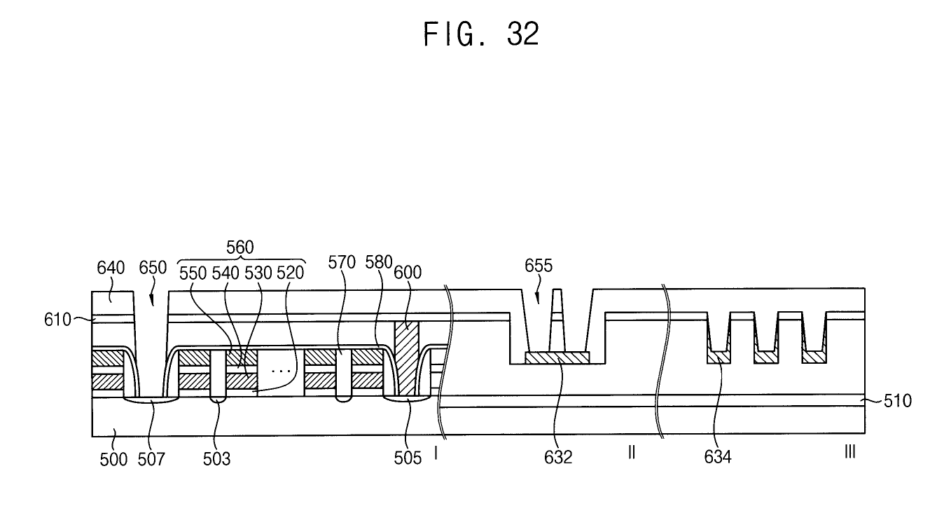

Referring to FIG. 32, a fourth insulation layer may be formed on the etch stop layer 610 and the first insulating interlayer 590 to sufficiently fill the trench 620. In example embodiments, the fourth insulation layer may be formed using a material substantially the same as that of the first insulating interlayer 590, and thus the first insulating interlayer 590 and the fourth insulation layer may be merged into a single layer. Hereinafter, this merged layer may be referred to as a first insulation layer 640.

Processes substantially the same as or similar to those illustrated with reference to FIGS. 15 to 18 may be performed.

Particularly, a first hard mask layer (not shown) and a second photoresist pattern (not shown) may be formed on the first insulating interlayer 640, and the first hard mask layer may be patterned using the second photoresist pattern as an etching mask. The first insulating interlayer 640 and the etch stop layer 610 may be partially removed using the patterned first hard mask layer to form a third opening 650 exposing the third impurity region 507 and a fourth opening 655 exposing the first resistance pattern 632.

The second photoresist pattern and the patterned first hard mask layer may be removed.

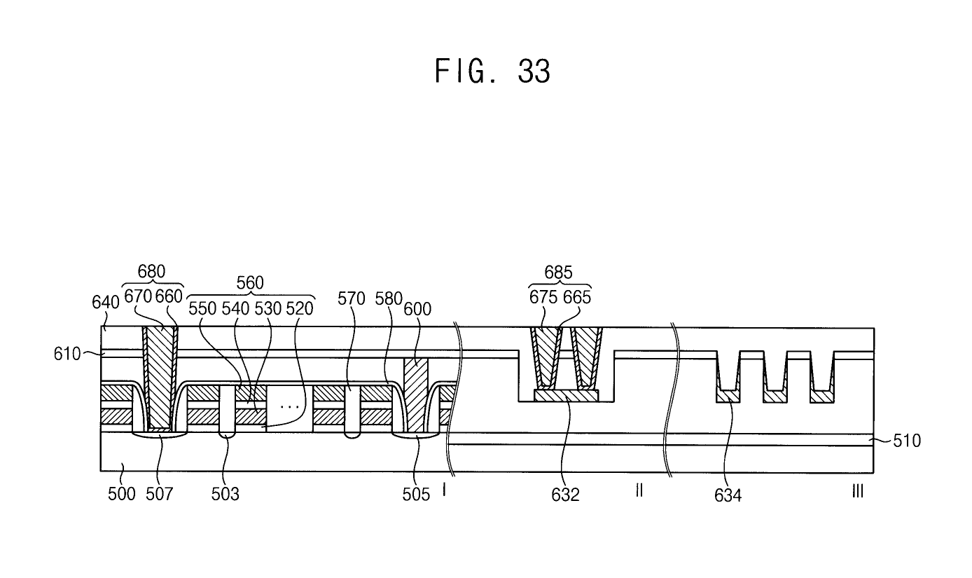

Referring to FIG. 33, processes substantially the same as or similar to those illustrated with reference to FIG. 19 may be performed.

First and second contact plugs 685 and 680 filling the third and fourth openings 650 and 655 may be formed on the exposed first resistance pattern 632 and the exposed third impurity region 507.

Particularly, a first barrier layer may be formed on the exposed top surfaces of the first resistance pattern 632 and the third impurity region 507 and sidewalls of the third and fourth openings 650 and 655, and a second conductive layer sufficiently filling the third and fourth openings 650 and 655 may be formed on the first barrier layer. The second conductive layer and the first barrier layer may be planarized until a top surface of the first insulating interlayer 640 may be exposed. In example embodiments, the first barrier layer may be formed using a metal or a metal nitride, and the second conductive layer may be formed using a low resistance metal, e.g., aluminum, copper, etc., a metal nitride and/or a metal silicide.

In example embodiments, the planarization process may be performed by a CMP process. The first resistance pattern 632 may have a top surface lower than that of the first insulating interlayer 640, and thus the first resistance pattern 632 may not be damaged during the CMP process. Accordingly, the CMP process may have a large process margin, and the first resistance pattern 632 may have good electrically characteristics.

Thus, the first contact plug 685 making direct contact with the top surface of the first resistance pattern 632 and filling the fourth opening 655 may be formed. Additionally, the second contact plug 680 making direct contact with the top surface of the third impurity region 507 and filling the third opening 650 may be formed.

The first contact plug 685 may include a first barrier layer pattern 665 and a first conductive layer pattern 675, and the second contact plug 680 may include a second barrier layer pattern 660 and a second conductive layer pattern 670. In example embodiments, the second contact plug 680 may serve as a bit line contact plug.

Referring to FIG. 26 again, a second insulating interlayer 720 may be formed on the first insulating interlayer 640 and the plugs 685 and 680, and a wiring 715 and a bit line 710 may be formed through the second insulating interlayer 720 to be electrically connected to the plugs 685 and 680.

In example embodiments, the second insulating interlayer 720 may be partially removed to form a fifth opening (not shown) exposing the plugs 685 and 680, and a second barrier layer may be formed on the exposed plugs 685 and 680, a sidewall of the fifth opening and the insulating interlayers 640 and 720. A third conductive layer sufficiently filling the fifth opening may be formed on the second barrier layer, and the third conductive layer and the second barrier layer may be planarized until a top surface of the second insulating interlayer 720 may be exposed to form the bit line 710 and the wiring 715. The second barrier layer may be formed using a metal or a metal nitride, and the third conductive layer may be formed using a metal, a metal nitride and/or a metal silicide. In example embodiments, the bit line 710 may be formed to extend in the first direction.

A protection layer 730 may be formed on the bit line 710, the wiring 715 and the second insulating interlayer 720 to manufacture the semiconductor device.

The method of manufacturing the semiconductor device in accordance with example embodiments may be applied not only to the SRAM device or the NAND flash memory device but also to other semiconductor devices having a resistance pattern including a metal and/or a metal silicide. Thus, the method may be applied to a dynamic random access memory (DRAM) device, a NOR flash memory device, a phase-change random access memory (PRAM) device, etc. Additionally, this method may be applied to semiconductor devices having a resistance pattern including other materials instead of a metal, e.g., an insulating material.

While example embodiments have been particularly shown and described, it will be understood by those of ordinary skill in the art that various changes in form and details may be made therein without departing from the spirit and scope of the present invention as defined by the following claims.

What is claimed is:

1. A semiconductor device, comprising:
a gate structure on a substrate, the gate structure including a first metal;
an insulating interlayer covering the gate structure on the substrate;
a resistance pattern in the insulating interlayer, the resistance pattern having a top surface lower than a top surface of the insulating interlayer and including a second metal different from the first metal at least at an upper portion thereof; and
a first contact plug through a first portion of the insulating interlayer, the first contact plug making direct contact with the upper portion of the resistance pattern.

2. The semiconductor device of claim 1, wherein the substrate is divided into an active region and a field region, and further comprising:
at least one second contact plug through a second portion of the insulating interlayer, the at least one second contact plug being electrically connected to the active region; and
a shared contact plug through the insulating interlayer, the shared contact plug making contact with a top surface of the gate structure and a top surface of the second contact plug.

3. The semiconductor device of claim 2, wherein the first contact plug and the shared contact plug have top surfaces substantially coplanar with each other.

4. The semiconductor device of claim 2, wherein the insulating interlayer includes an etch stop layer having a bottom surface coplanar with a top surface of the second contact plug.

5. The semiconductor device of claim 4, further comprising:
a third contact plug through a third portion of the insulating interlayer and the etch stop layer, the third contact plug making contact with a top surface of the second contact plug that does not contact the shared contact plug and having a top surface substantially coplanar with a top surface of the first contact plug.

6. The semiconductor device of claim 1, wherein the resistance pattern includes tungsten or tungsten silicide.

7. The semiconductor device of claim 1, further comprising:
an alignment key in the insulating interlayer, the alignment key having a bottom surface coplanar with a bottom surface of the resistance pattern and including the second metal.

8. The semiconductor device of claim 1, wherein a bottom surface of the resistance pattern is lower than a top surface of the gate structure.

9. The semiconductor device of claim 1, wherein a bottom surface of the resistance pattern is higher than a top surface of the gate structure.

10. The semiconductor device of claim 1, wherein the gate structure includes a tunnel insulation layer pattern, a floating gate, a dielectric layer pattern, and a control gate sequentially stacked on the substrate, and
wherein the control gate includes the first metal.

11. A semiconductor device, comprising:
a gate structure on a cell region of a substrate that is divided into an active region and a field region, and includes the cell region and a logic region, the gate structure including a first metal;
an insulating interlayer covering the gate structure on the substrate;
a resistance pattern in the insulating interlayer in the logic region, the resistance pattern having a top surface lower than a top surface of the insulating interlayer and including a second metal different from the first metal;
a first contact plug through a portion of the insulating interlayer, the first contact plug making contact with a top surface of the resistance pattern;
at least one second contact plug through the insulating interlayer in the cell region, the at least one second contact plug being electrically connected to the active region; and
a shared contact plug through the insulating interlayer in the cell region, the shared contact plug making contact with a top surface of the gate structure and a top surface of the at least one second contact plug.

12. A semiconductor device, comprising:
a substrate including a cell region, a logic region, and a scribe lane region;
a gate structure on the substrate in the cell region;
an insulating interlayer on the substrate in the cell region, the logic region, and the scribe lane region;
a resistance pattern in the insulating interlayer on the substrate in the logic region; and
a first contact plug through a portion of the insulating interlayer on the substrate in the logic region;
wherein the gate structure includes a first metal, and
wherein the resistance pattern includes a second metal different from the first metal.

13. The semiconductor device of claim 12, wherein the resistance pattern has a top surface lower than a top surface of the insulating interlayer.

14. The semiconductor device of claim 12, wherein the first contact plug makes direct contact with an upper portion of the resistance pattern.

15. The semiconductor device of claim 12, wherein the resistance pattern includes tungsten.

16. The semiconductor device of claim 12, wherein the resistance pattern includes tungsten silicide.

17. The semiconductor device of claim 12, wherein the gate structure includes a tunnel insulation layer pattern, a floating gate, a dielectric layer pattern, and a control gate sequentially stacked on the substrate.

18. The semiconductor device of claim 12, wherein a top surface of the resistance pattern is lower than a top surface of the insulating interlayer.

19. The semiconductor device of claim 12, further comprising:
an alignment key in the insulating interlayer on the substrate in the scribe lane region.

20. The semiconductor device of claim 19, wherein the alignment key has a bottom surface that is coplanar with a bottom surface of the resistance pattern.
